(19) United States
(12) Patent Application Publication
(10) Pub. No.: US 2025/0118697 A1
(43) Pub. Date: Apr. 10, 2025

(54) PACKAGE STRUCTURE AND METHODS OF FORMING THE SAME

(71) Applicant: Taiwan Semiconductor Manufacturing Company Limited, Hsinchu (TW)

(72) Inventors: Jui Shen Chang, Taichung City (TW); Chen-Nan Chiu, Hsinchu City (TW); Yao-Chun Chuang, Hsinchu City (TW); Chang-Jung Hsueh, Taipei (TW); Ming-Da Cheng, Hsinchu (TW)

(21) Appl. No.: 18/787,373

(22) Filed: Jul. 29, 2024

Related U.S. Application Data
(63) Continuation-in-part of application No. 18/587,838, filed on Feb. 26, 2024.
(60) Provisional application No. 63/587,798, filed on Oct. 4, 2023.

(51) Int. Cl. H01L 23/00; H01L 23/055; H01L 23/31; H01L 23/36; H01L 23/538; H01L 25/065

(52) U.S. Cl. CPC H01L 24/29; H01L 23/055; H01L 23/36; H01L 24/27; H01L 23/3107; H01L 23/5383; H01L 24/16; H01L 24/32; H01L 24/33; H01L 24/73; H01L 25/0655; H01L 2224/16227; H01L 2224/2741; H01L 2224/29019; H01L 2224/29083; H01L 2224/29105; H01L 2224/29109; H01L 2224/29111; H01L 2224/29139; H01L 2224/29147; H01L 2224/29193; H01L 2224/32221; H01L 2224/33181; H01L 2224/73204

(57) ABSTRACT

A package structure includes a package substrate, a chip on the package substrate, a package lid on the chip, and a structure between the chip and the package lid. The structure may include a thermal interface material (TIM) layer, and a metal layer between the TIM layer and at least one of the chip or the package lid and configured to inhibit formation of an intermetallic compound (IMC) layer. A method of making the package structure includes forming a metal layer including a high-texture structure on at least one of a chip or a package lid, attaching the chip to a package substrate, forming a thermal interface material (TIM) layer over the chip, and attaching the package lid to the package substrate over the chip so that the chip, the TIM layer and the metal layer are disposed between the package lid and the package substrate.

### RELATED APPLICATIONS

This application is a continuation-in-part (CIP) of U.S. patent application Ser. No. 18/587,838 entitled “Package Structure Including a Heat Dissipation Structure and Methods of Forming the Same,” filed on Feb. 26, 2024, which claims the benefit of priority from U.S. Provisional Application Ser. No. 63/587,798 entitled “Package Structure” and filed on Oct. 4, 2023, the entire contents of both of which are incorporated herein by reference for all purposes.

### BACKGROUND

In electronic devices and other semiconductor components, heat may be generated during operation. Efficiently dissipating the generated heat may help to maintain the electronic devices' performance and prevent overheating. Otherwise, overheating may lead to performance degradation or even permanent damage.

A package structure (e.g., semiconductor packages) may sometimes include a thermal interface material (TIM) layer to help dissipate heat generated in the package structure. The TIM layer may enhance the transfer of heat between two surfaces with different thermal properties. The TIM layer may be located, for example, between an interposer module (e.g., package module) and a package lid (e.g., heat sink). The TIM layer may improve thermal contact by filling the microscopic gaps and irregularities between the interposer module and package lid.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a package structure according to one or more embodiments.

FIG. 1B is a plan view (e.g., top-down view) of the package structure according to one or more embodiments.

FIG. 1C is a detailed vertical cross-sectional view of a portion of the package structure according to one or more embodiments.

FIG. 1D is a detailed vertical cross-sectional view of a portion of the first metal layer and the second metal layer in the package structure according to one or more embodiments.

FIG. 2A is a vertical cross-sectional view of an intermediate structure including the package substrate having package substrate upper bonding pads and package substrate lower bonding pads, according to one or more embodiments.

FIG. 2B illustrates a vertical cross-sectional view of an intermediate structure in which the interposer module may be mounted on the package substrate, according to one or more embodiments.

FIG. 2C illustrates a vertical cross-sectional view of an intermediate structure including the interposer module in a flux cleaning process (e.g., flux jetting process) according to one or more embodiments.

FIG. 2D illustrates a vertical cross-sectional view of an intermediate structure in which the package underfill layer may be formed on the package substrate according to one or more embodiments.

FIG. 2E illustrates a vertical cross-sectional view of an intermediate structure in which the TIM layer may be formed on (e.g., attached to) the first metal layer according to one or more embodiments.

FIG. 2F illustrates a vertical cross-sectional view of an intermediate structure in which the adhesive layer may be applied to the package substrate according to one or more embodiments.

FIG. 2G illustrates a vertical cross-sectional view of an intermediate structure in which the package lid may be attached to (e.g., mounted on) the package substrate according to one or more embodiments.

FIG. 2H illustrates a vertical cross-sectional view of an intermediate structure in which a plurality of solder balls may be formed on the package substrate according to one or more embodiments.

FIG. 3 is a flow chart illustrating a method of making the package structure according to one or more embodiments.

FIG. 4A is a vertical cross-sectional view of the package structure having the first alternative design, according to one or more embodiments.

FIG. 4B is a detailed vertical cross-sectional view of a portion of the first metal layer and the second metal layer in the package structure having the first alternative design according to one or more embodiments.

FIG. 5A is a vertical cross-sectional view of the package structure having the second alternative design, according to one or more embodiments.

FIG. 5B is a detailed vertical cross-sectional view of a portion of the first metal layer and the second metal layer in the package structure having the second alternative design according to one or more embodiments.

FIG. 6 is a vertical cross-sectional view of the package structure having the third alternative design, according to one or more embodiments.

FIG. 7A is a vertical cross-sectional view of the package structure having the fourth alternative design, according to one or more embodiments.

FIG. 7B is a plan view (e.g., top-down view) of the package structure having a fourth alternative design according to one or more embodiments.

FIG. 8 is a flow chart illustrating an alternative method of making the package structure according to one or more embodiments.

FIG. 9 is a vertical cross-sectional view of the package structure having a fifth alternative design, according to one or more embodiments.

FIG. 10 is a vertical cross-sectional view of the package structure having a sixth alternative design, according to one or more embodiments.

FIG. 11 is a vertical cross-sectional view of the package structure having a seventh alternative design, according to one or more embodiments.

FIG. 12 is a vertical cross-sectional view of the package structure having an eighth alternative design, according to one or more embodiments.

FIG. 13 is a vertical cross-sectional view of the package structure having a ninth alternative design, according to one or more embodiments.

FIG. 14 is a vertical cross-sectional view of the package structure having a tenth alternative design, according to one or more embodiments.

FIG. 15 is a vertical cross-sectional view of the package structure having an eleventh alternative design, according to one or more embodiments.

FIG. 16 is a vertical cross-sectional view of the package structure having a twelfth alternative design, according to one or more embodiments.

FIG. 17 is a vertical cross-sectional view of the package structure having a thirteenth alternative design, according to one or more embodiments.

FIG. 18 is a vertical cross-sectional view of the package structure 100 having a fourteenth alternative design, according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within the same thickness range.

The TIM layer may include, for example, a gel-TIM layer. In at least one embodiment, the TIM layer may include a thermal grease or paste including a mixture of metal particles suspended in a silicone or hydrocarbon-based grease or paste. The TIM layer may include a thermal adhesive that includes metal particles mixed with an adhesive resin that cures after application. The TIM layer may include thermal pads including metal particles or metal foils or films. The TIM layer may also include a metal-infused graphite sheet. A metal TIM layer including, for example, In, Sn, Ga and their alloys, may be a good choice for thermal dissipation due to its excellent thermal conductivity. The TIM layer may include one or more metal materials.

A metal layer (e.g., metallization layer) on the backside of the interposer module may be used to enhance adhesion between the metal TIM layer, the interposer module (e.g., semiconductor chip, system on chip (SOC), etc.) and the package lid. However, formation of an intermetallic compound (IMC) layer between the metal layer and the metal TIM layer may cause Kirkendall voids which may increase thermal resistance.

One or more embodiments of the present disclosure may include a package structure (e.g., flip chip multi-chip module (FC-MCM)) including an innovative metal layer on an interposer module (e.g., including semiconductor, silicon, etc.) and a package lid of the package structure for better thermal dissipation. In at least one embodiment, the package structure may include a package substrate, an interposer module on the package substrate, a package lid on the interposer module, and a structure (e.g., heat dissipation structure) between the interposer module and the package lid. The structure may include, for example, a thermal interface material (TIM) layer, and a metal layer adjacent the TIM layer and including a textured (e.g., highly textured) structure. In at least one embodiment the metal layer may include a Cu (111) layer.

A Cu(111) layer may include a textured structure. Cu(111) may be referred to as a “textured structure”, “textured copper”, “high-texture structure” or “high-texture copper”. A surface of the Cu(111) may be highly textured (e.g., have a high roughness). However, the roughness of the surface may be modified (e.g., by adjusting the parameter of the plating process) to be close to that of a Cu(100) layer (e.g., a non-textured structure) which may have a higher amount of random copper than a Cu(111) layer.

The metal layer having a textured structure (e.g., a Cu (111) layer) may provide several advantages and benefits to the package structure. In particular, the metal layer may inhibit an interdiffusion of the metallization (e.g., copper) and the metal TIM layer. The metallization may, therefore, inhibit the formation of an IMC layer at an interface between the metal layer and the metal TIM layer resulting in fewer Kirkendall voids at the interface. In addition, the metal layer (e.g., Cu (111) layer) may have a high thermal conductivity. As a result, the metal layer having a textured structure (e.g., highly textured Cu (111) layer) may be used to improve heat dissipation efficiency in the package structure.

Further, the composition and grain orientation of the textured metal layer (e.g., Cu (111) metallization layer) may be analyzed by an electrical die sorting (EDS) process and electron backscatter diffraction (EBSD), respectively. In addition, the length, width, and thickness of the metal layer may be detected from microstructure.

In at least one embodiment, the package structure may include a package substrate including a ball grid array (BGA), an interposer module (e.g., SOC) on the package substrate and including a textured metal layer (e.g., high-texture Cu (111) metallization layer), a package lid attached to the package substrate over the interposer module and including a textured metal layer (e.g., high-texture Cu (111) metallization layer), an adhesive layer attaching the package lid to the package substrate, a metal TIM layer between the interposer module and the package lid, metal interconnect structures (e.g., copper pillars, solder bumps, etc.) connecting the interposer module to the package substrate, and a package underfill layer between the interposer module and the package substrate. In at least one embodiment, the metal layer of the interposer module or the metal layer of the package lid may include a non-textured structure (e.g., a non-textured metallization layer). The non-textured structure may include, for example, a Cu(100) layer.

It should be noted that the term “textured structure” may be understood as referring to a structure containing grains oriented in a particular direction. The textured structure may be composed of columnar grains. The columnar grain textured structure may include thermally conductive materials such as gold (Au), copper (Cu), or aluminum (Al), and may include metal grain with crystal orientation of a columnar structure, e.g., copper with (111) orientation (Cu(111)), copper with (211) orientation (Cu(211)), gold with (111) orientation (Au(111)), and Silver with (111) orientation (Ag(111)). In particular, the term “high-texture structure” may refer to a structure in which an amount of grain oriented in a particular direction (e.g., Cu(111) or columnar copper with (111) orientation) is greater than 75%, in some embodiments greater than 85%, and in another embodiment, greater than 95%.

The high-texture structure may include twin boundaries. A twin boundary may include a type of grain boundary where adjoining crystal lattices mirror each other. The twin boundary may be characterized by a symmetrical arrangement of atoms across the twin boundary. In at least one embodiment, the high-texture structure may include a high density of twin boundaries. In at least one embodiment, a density of the twin boundaries in the high-texture structure among all crystal grain boundaries may be greater than 10 μm⁻¹, in some embodiments greater than 15 m⁻¹, in another embodiment greater than 20 m⁻¹. In at least one embodiment, the density of twin boundaries among all crystal grain boundaries may be greater than 70%. In at least one embodiment, the density of twin boundaries among all crystal grain boundaries may be greater than 95%.

The package structure may also include one or more memory devices on the package substrate adjacent the package lid. The memory devices may include, for example, dynamic random access memory (DRAM). The memory devices may be mounted on a memory substrate (DRAM substrate) that is attached to the package substrate by memory solder (DRAM solder, a memory underfill layer (DRAM underfill) between the memory substrate and the package substrate.

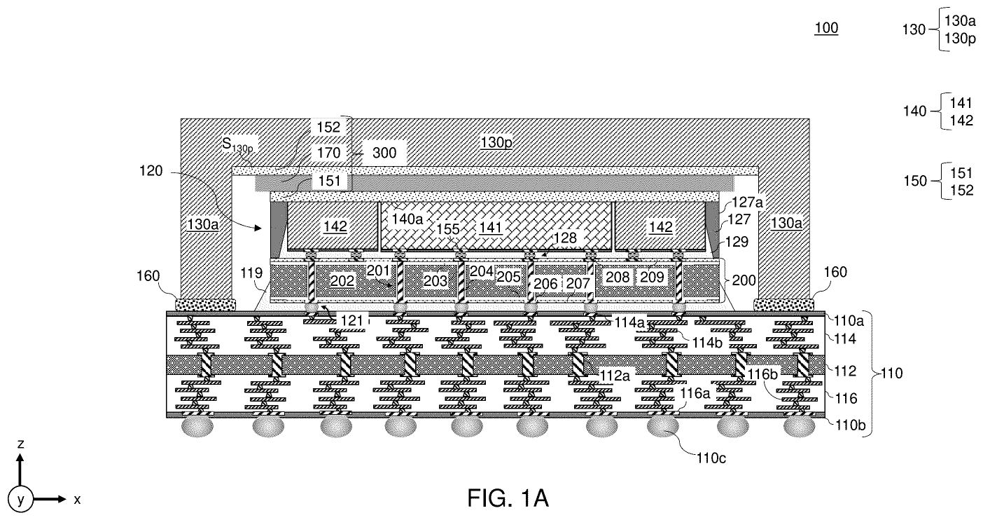

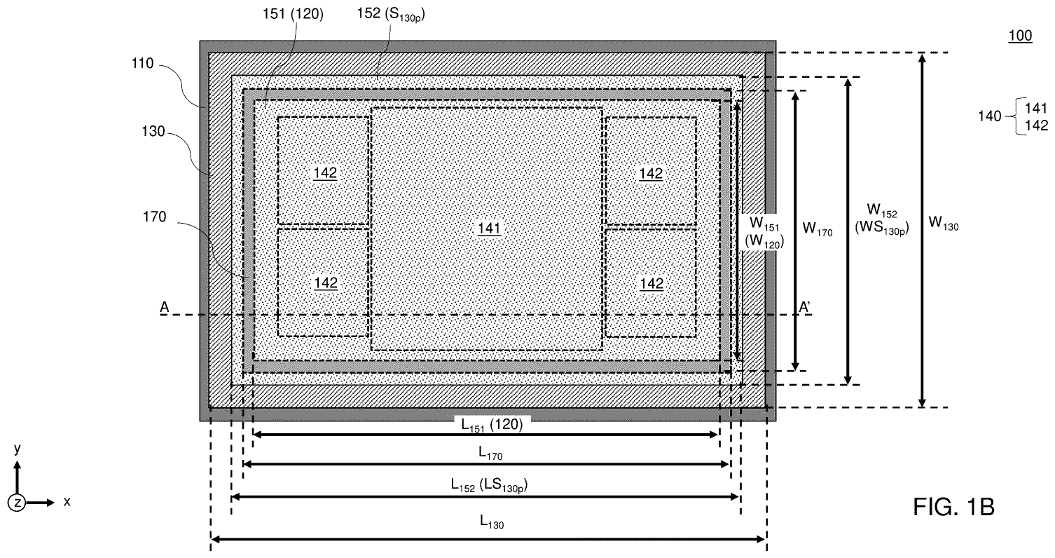

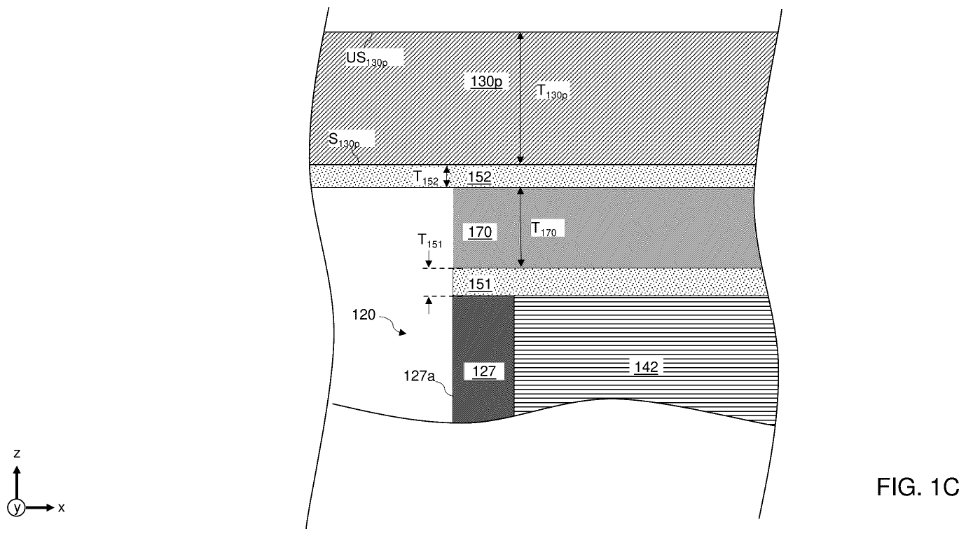

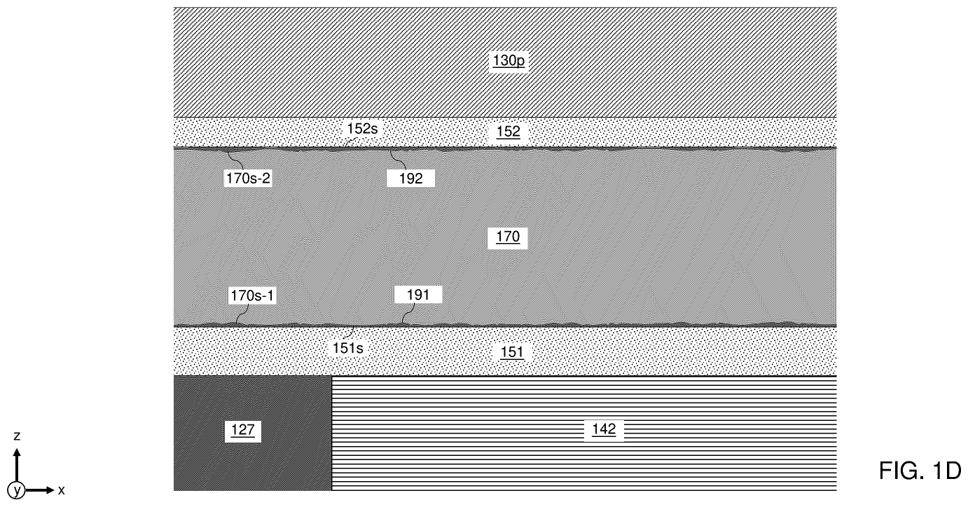

FIG. 1A is a vertical cross-sectional view of a package structure 100 according to one or more embodiments. FIG. 1B is a plan view (e.g., top-down view) of the package structure 100 according to one or more embodiments. The vertical cross-sectional view in FIG. 1A is along the line A-A′ in FIG. 1B. FIG. 1C is a detailed vertical cross-sectional view of a portion of the package structure 100 according to one or more embodiments. FIG. 1D is a detailed vertical cross-sectional view of a portion of the first metal layer 151 and the second metal layer 152 in the package structure 100 according to one or more embodiments.

As illustrated in FIG. 1A, the package structure 100 may include a package substrate 110 and an interposer module 120 on the package substrate 110. The package structure 100 may also include a package lid 130 on the interposer module 120. The package lid 130 may include a package lid foot portion 130a attached to the package substrate 110. The package lid 130 may also include a package lid plate portion 130p connected to the package lid foot portion 130a.

The package structure 100 may also include a structure 300 between the interposer module 120 and the package lid 130. The structure 300 may include a TIM layer 170 and a metal layer 150 adjacent the TIM layer 170 and including a textured structure. The metal layer 150 may include a first metal layer 151 between the TIM layer 170 and the interposer module 120, and a second metal layer 152 between the package lid 130 and the TIM layer 170. The textured structure may be included on both the a first metal layer 151 and the second metal layer 152. That is, each of the first metal layer 151 and the second metal layer 152 may include a textured metal layer. In at least one embodiment, in each of the first metal layer 151 and the second metal layer 152, the amount of columnar grain (e.g., Cu(111) or columnar copper with (111) orientation) may be greater than 95%.

The package substrate 110 may include a cored or coreless substrate. In at least one embodiment, for example, the package substrate 110 may include a core 112, a package substrate upper dielectric layer 114 formed on the core 112 (e.g., a first side or chip-side of the package substrate 110), and a package substrate lower dielectric layer 116 formed on the core 112 (e.g., a second side or board-side of the package substrate 110). In particular, the package substrate 110 may include a build-up film substrate such as an Ajinomoto build-up film (ABF) substrate. That is, in at least one embodiment, each of the package substrate upper dielectric layer 114 and the package substrate lower dielectric layer 116 may be described as an ABF layer.

The core 112 may help to provide rigidity to the package substrate 110. The core 112 may include, for example, an epoxy resin such as a bismaleimide triazine epoxy (BT epoxy) and/or a woven glass laminate. The core 112 may alternatively or in addition include an organic material such as a polymer material. In particular, the core 112 may include a dielectric polymer material such as polyimide (PI), benzocyclo-butene (BCB) polymer, or polybenzobisoxazole (PBO). Other suitable dielectric materials are within the contemplated scope of disclosure.

The core 112 may include one or more through vias 112a. The through vias 112a may extend from a lower surface of the core 112 to an upper surface of the core 112. The through vias 112a may allow an electrical connection between the package substrate upper dielectric layer 114 and the package substrate lower dielectric layer 116. The through vias 112a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate upper dielectric layer 114 may be formed on an upper surface of the core 112. The package substrate upper dielectric layer 114 may include a plurality of layers and, in particular, may include a build-up film (e.g., ABF). The package substrate upper dielectric layer 114 may also include an organic material such as a polymer material. In particular, the package substrate upper dielectric layer 114 may include a dielectric polymer material such as polyimide (PI), benzocyclobutene (BCB), or polybenzobisoxazole (PBO). Other suitable dielectric materials are within the contemplated scope of disclosure.

The package substrate upper dielectric layer 114 may include one or more package substrate upper bonding pads 114a on a chip-side surface of the package substrate upper dielectric layer 114. The package substrate upper bonding pads 114a may be exposed on the chip-side surface of the package substrate upper dielectric layer 114. The package substrate upper dielectric layer 114 may also include one or more metal interconnect structures 114b. The metal interconnect structures 114b may electrically couple the package substrate upper bonding pads 114a to the through vias 112a in the core 112. The metal interconnect structures 114b may include metal layers (e.g., copper traces) and metal vias connecting the metal layers. The package substrate upper bonding pads 114a and the metal interconnect structures 114b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate upper passivation layer 110a may be formed on the chip-side surface of the package substrate upper dielectric layer 114. The package substrate upper passivation layer 110a may at least partially cover the package substrate upper bonding pads 114a. The upper passivation layer 110a may include silicon oxide, silicon nitride, low-k dielectric materials such as carbon-doped oxides, extremely low-k dielectric materials such as porous carbon doped silicon dioxide, a combination thereof or other suitable material.

The package substrate lower dielectric layer 116 may be formed on a lower surface of the core 112. The package substrate lower dielectric layer 116 may also include a plurality of layers and, in particular, may include a build-up film (e.g., ABF). The package substrate lower dielectric layer 116 may also include an organic material such as a polymer material. In particular, the package substrate lower dielectric layer 116 may include a dielectric polymer material such as polyimide (PI), benzocyclobutene (BCB), or polybenzobisoxazole (PBO). Other suitable dielectric materials are within the contemplated scope of disclosure.

The package substrate lower dielectric layer 116 may include one or more package substrate lower bonding pads 116a on a board-side surface of the package substrate lower dielectric layer 116. The package substrate lower dielectric layer 116 may also include one or more metal interconnect structures 116b. The metal interconnect structures 116b may electrically couple the package substrate lower bonding pads 116a to the through vias 112a in the core 112. The metal interconnect structures 116b may include metal layers (e.g., copper traces) and metal vias connecting the metal layers. The package substrate lower bonding pads 116a and the metal interconnect structures 116b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate lower passivation layer 110b may be formed on the board-side surface of the package substrate lower dielectric layer 116. The package substrate lower passivation layer 110b may at least partially cover the package substrate lower bonding pads 116a. The package substrate lower passivation layer 110b may include silicon oxide, silicon nitride, low-k dielectric materials such as carbon-doped oxides, extremely low-k dielectric materials such as porous carbon doped silicon dioxide, a combination thereof or other suitable material.

A ball-grid array (BGA) including a plurality of solder balls 110c may be formed on the board-side surface of the package substrate 110. The solder balls 110c may allow the package structure 100 to be securely mounted on a substrate such as a printed circuit board (PCB) and electrically coupled to the PCB substrate. The solder balls 110c may contact the package substrate lower bonding pads 116a, respectively. The solder balls 110c may therefore be electrically connected to the package substrate upper bonding pads 114a by way of metal interconnect structures 116b, the through vias 112a and the metal interconnect structures 114b. The solder balls 110c of the BGA may be formed in a two-dimensional array on the board-side surface of the package substrate 110. The solder balls 110c may be located, for example, under the package lid foot portion 130a and under the interposer module 120.

As illustrated in FIG. 1A, the package substrate 110 may have a width in the x-direction that is greater than a width of the interposer module 120 in the x-direction. The package substrate 110 may also have a length in the y-direction that is greater than a length of the interposer module 120 in the y-direction. The interposer module 120 may be located in a central portion of the package substrate 110. The interposer module 120 may include an interposer 200 and one or more dies 140 (e.g., semiconductor dies, top dies, etc.; see FIG. 1B) on the interposer 200. The interposer module 120 may be attached by C4 bumps 121 to the package substrate upper bonding pads 114a in the package substrate 110. The C4 bumps 121 may include a metal pillar (not shown) and a solder bump (e.g., SnAg solder bump) on the metal pillar. The solder bump may be collapsed to join the metal pillar of the C4 bump 121 to the package substrate upper bonding pads 114a.

A package underfill layer 119 may be formed on the package substrate 110 under and around the interposer module 120. The package underfill layer 119 may also be formed around the C4 bumps 121. The package underfill layer 119 may thereby securely fix the interposer module 120 to the package substrate 110. The package underfill layer 119 may be formed of an epoxy-based polymeric material. Other suitable materials may be used for the package underfill layer 119.

The interposer module 120 is not limited to any particular configuration. The interposer module 120 may include, for example, a flip chip-chip scale package design, a chip-on-wafer-on-substrate design, an integrated fan-out design, and so on. In at least one embodiment, the interposer 200 may be omitted from the interposer module 120. In such embodiments, the dies 140 may be attached directly to the package substrate 110.

The interposer 200 of the interposer module 120 may include an inorganic interposer. The interposer 200 may include a semiconductor material layer 202. In at least one embodiment, the semiconductor material layer 202 may include a silicon-based semiconductor material. The semiconductor material layer 202 may include single crystalline silicon or polycrystalline silicon. The semiconductor material layer 202 may be undoped or doped with electrical dopants such as p-type dopants or n-type dopants.

The interposer 200 may include a plurality of via cavities 201 in the semiconductor material layer 202. The via cavities 201 may extend in the z-direction through an entire thickness of the semiconductor material layer 202. A lateral dimension (such as the diameter) of the via cavities 201 may be in a range from 0.5 micron to 10 microns, such as from 1 micron to 6 microns, although lesser and greater lateral dimensions may also be used. In at least one embodiment, the pattern of the array of via cavities 201 may have a two-dimensional periodicity over the interposer 200.

An insulating liner 203 may be formed in peripheral portions of the via cavities 201 and on an upper surface of the semiconductor material layer 202. The insulating liner 203 may include, for example, silicon oxide, silicon nitride, low-k dielectric materials such as carbon-doped oxides, extremely low-k dielectric materials such as porous carbon doped silicon dioxide, a combination thereof or other suitable material. The insulating liner 203 may have a thickness in a range from 1% to 20%, such as from 2% to 5% of the lateral dimension of the via cavities 201.

A plurality of through silicon vias (TSVs) 204 may be located in the plurality of via cavities 201, respectively. The TSVs 204 may include at least one conductive material, such as at least one metallic material, in a central portion of the via cavities 201. The TSVs 204 and the insulating liner 203 may substantially fill the via cavities 201. The TSVs 204 may include, for example, a combination of a metallic material (such as TiN, TaN, WN, MoN, TiC, TaC, WC, etc.) and a metallic fill material (such as Cu, Co, Ru, Mo, W, etc.). Other suitable metallic materials and metallic fill materials are within the contemplated scope of disclosure.

The interposer 200 may also include a lower insulating layer 205 on a bottom surface of the semiconductor material layer 202. The lower insulating layer 205 may join the insulating liner 203 in the via cavities 201. The lower insulating layer 205 may include a material that is the same or similar to the material of the insulating liner 203. The lower insulating layer 205 may include, for example, silicon oxide, silicon nitride, low-k dielectric materials such as carbon-doped oxides, extremely low-k dielectric materials such as porous carbon doped silicon dioxide, a combination thereof or other suitable material.

The interposer 200 may further include interposer lower bonding pads 206 on the TSVs 204 on a board-side surface of the interposer 200. The interposer 200 may further include a lower passivation layer 207 on the board-side surface of the interposer 200. The lower passivation layer 207 may at least partially cover the interposer lower bonding pads 206. The C4 bumps 121 may be connected to the interposer lower bonding pads 206 on the board-side surface of the interposer 200, respectively. In at least one embodiment, the C4 bumps 121 may include underbump metallurgy (UBM) layers on the interposer lower bonding pads 206. The C4 bumps 121 may be located at least partially on the lower insulating layer 205. The lower insulating layer 205 may serve to electrically insulate the C4 bumps 121 from the semiconductor material layer 202.

The interposer 200 may further include interposer upper bonding pads 208 on the TSVs 204 on a chip-side surface of the interposer 200. The interposer 200 may further include an upper passivation layer 209 on the board-side surface of the interposer 200. The upper passivation layer 209 may at least partially cover the upper interposer bonding pads 208. The interposer lower bonding pads 206 and interposer upper bonding pads 208 may be substantially similar to the package substrate lower bonding pads 116a and package substrate upper bonding pads 114a. The lower passivation layer 207 and upper passivation layer 209 may be substantially similar to the package substrate lower passivation layer 110b and package substrate upper passivation layer 110a.

In at least one embodiment, the interposer module 120 may include a redistribution layer (RDL) structure (not shown) located on the chip-side surface of the interposer 200. The RDL structure may include a plurality of polymer layers and a plurality of redistribution layers stacked alternately. The redistribution layers may include a metal such as copper, aluminum, nickel, titanium, a combination thereof or other suitable metals. The redistribution layers may include metallic connection structures, i.e., metallic structures that provide electrical connection between nodes in the structure. In at least one embodiment, the redistribution layers may include a plurality of traces (lines) and a plurality of vias connecting the plurality traces to each other. The traces may be respectively located on the polymer layers and may extend in the x-direction (first horizontal direction) and y-direction (second horizontal direction) on an upper surface of the polymer layers. The redistribution layers may interconnect the dies 140 and/or connect the dies 140 to the TSVs 204 in the interposer 200.

The dies 140 may be attached to the chip-side surface of the interposer 200 (or alternatively, to the RDL structure in embodiments in which the RDL structure is present). In particular, the dies 140 may be flip-chip mounted on the upper surface of the interposer 200. That is, an active region of the dies 140 may face the interposer 200 and a bulk semiconductor region of the dies 140 may be opposite the active region.

The dies 140 may include a substantially coplanar upper surface 140a (e.g., upper surface of the bulk semiconductor region). In particular, the upper surface 140a of the dies 140 may be located at a same height measured from an upper surface of the upper passivation layer 209.

In at least one embodiment, the dies 140 may be bonded to the upper interposer bonding pads 208 on the chip-side surface of the interposer 200 by microbumps 128. The microbumps 128 may each include a copper post and a solder bump on the copper post. In at least one embodiment, the dies 140 may include one or more die bonding pads 155 electrically coupled to an active region of the dies 140. The microbumps 128 may contact the die bonding pads 155 of the dies 140. The die bonding pads 155 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

An interposer module underfill layer 129 may be formed (e.g., individually or collectively) under and around each of the dies 140. The interposer module underfill layer 129 may also be formed around the microbumps 128. The interposer module underfill layer 129 may thereby fix each of the dies 140 to the interposer 200. The interposer module underfill layer 129 may be formed of an epoxy-based polymeric material. Other suitable metal materials are within the contemplated scope of disclosure.

Instead of utilizing the microbumps 128 and interposer module underfill layer 129, the dies 140 may alternatively be bonded to the interposer 200 by a hybrid bond which may also be known as direct bonding or wafer-to-wafer bonding. The hybrid bond may include a metallic portion and a dielectric portion. In at least one embodiment, the hybrid bond may include a metal-metal bond and an oxide-oxide bond. In particular, the hybrid bond may include a bond between the die bonding pads 155 and the interposer upper bonding pads 209, and a bond between dielectric layers (e.g., oxide layers) on the dies 140 and dielectric layers (e.g., oxide layers) on the interposer 200.

The dies 140 may include a first die 141 and a second die 142 adjacent the first die 141. Each of the dies 140 may include, for example, a singular semiconductor die structure, a system-on-chip die, or a system-on-integrated chips die, and may be implemented by chip-on-wafer-on-substrate technology or integrated fan-out on substrate technology. In particular, each of the semiconductor dies 140 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide I/O die, a M-RAM die, a R-RAM die, a NAND die, static random access memory (SRAM), etc.), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an IPD die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other dies are within the contemplated scope of this disclosure. In at least one embodiment, the first die 141 may include a primary die (e.g., system-on-chip die) and the second die 142 may include an ancillary die (e.g, DRAM die, HBM die, etc.) that supports an operation of the primary die.

A sidewall of the dies 140 (e.g., die sidewall) may include one or more metal layers (not shown). The metal layers may include, for example, an adhesion layer, a diffusion barrier layer, and an anti-oxidation layer (e.g., a layer including gold).

The interposer module 120 may also include a molding material layer 127 on the interposer 200, on and around the dies 140 and between the dies 140. The molding material layer 127 may be formed on (e.g., cover) and bonded to one or more of the die sidewalls (e.g., all of the die sidewalls) on the dies 140. In at least one embodiment, the dies 140 may be substantially “embedded” within the molding material layer 127. The molding material layer 127 may also be formed on and bonded to a surface of the upper passivation layer 209 of the interposer 200 (or the RDL structure, if present).

An upper surface of the molding material layer 127 may be substantially uniform (e.g., flat). The upper surface of the molding material layer 127 may also be substantially coplanar with the upper surface 140a of the dies 140. An outer sidewall of the molding material layer 127a may be substantially aligned with an outer sidewall of the interposer 200. In at least one embodiment, an outer sidewall of the interposer module 120 may be constituted at least in part by the outer sidewall of the molding material layer 127a and at least in part by the outer sidewall of the interposer 200.

In at least one embodiment, the molding material layer 127 may be formed of a curable material that may cure to form a hard, solid structure. The molding material layer 127 may include, for example, epoxy molding compound (EMC). In at least one embodiment, the molding material layer 127 may include a polymeric material and in particular, an epoxy-based polymeric material. Other suitable molding materials may be used.

In at least one embodiment, the molding material layer 127 may have a coefficient of thermal expansion (CTE) that is substantially similar to a CTE of the interposer 200 (e.g., a CTE of silicon). In at least one embodiment, the molding material layer 127 may include an added material (e.g., filler material) for improving a property of the molding material layer 127 (e.g., thermal conductivity, CTE, etc.). The added material may include, for example, metal powder, metal oxide powder, etc. Other materials in the molding material layer 127 are within the contemplated scope of the disclosure.

The package structure 100 may also include a structure 300 on the interposer module 120. The structure 300 may include a first metal layer 151, a TIM layer 170 on the first metal layer 151, and a second metal layer 152 on the TIM layer 170.

The first metal layer 151 may contact the upper surface 140a of the dies 140. The first metal layer 151 may also contact the upper surface of the molding material layer 127. A sidewall of the first metal layer 151 may be substantially aligned with the outer sidewall of the molding material layer 127a around an entire periphery of the first metal layer 151. The first metal layer 151 may include a Cu (111) layer. Other materials such as silver, graphite, etc. may alternatively or additionally be included in the first metal layer 151.

With reference to FIG. 1D, for example, the first metal layer 151 may have a textured structure (e.g., a Cu (111) layer). An interaction (e.g., reaction) between the first metal layer 151 and the TIM layer 170 may cause the formation of a lower IMC layer 191 at an interface between the first metal layer 151 and the TIM layer 170. The lower IMC layer 191 may be bounded, for example, by a surface 151s of the first metal layer 151 and a lower surface 170s-1 of the TIM layer 170.

The textured structure of the first metal layer 151 may provide several advantages and benefits to the package structure 100. In particular, the first metal layer 151 may inhibit an interdiffusion of the metallization (e.g., copper) and the TIM layer 170 (e.g., metal TIM layer). The first metal layer 151 may, therefore, inhibit the formation of the lower IMC layer 191 at the interface between the first metal layer 151 and the TIM layer 170 resulting in fewer Kirkendall voids at the interface. The first metal layer 151 may result in fewer Kirkendall voids by reducing a thickness of the lower IMC layer 191 formed at the interface.

In addition, the first metal layer 151 (e.g., Cu (111) layer) may have a high thermal conductivity. In at least one embodiment, the first metal layer 151 may have a thermal conductivity of 390 W/(m·K) or more. The first metal layer 151 (e.g., highly textured Cu (111)) may, therefore, be used to improve heat dissipation efficiency in the package structure 100.

The TIM layer 170 may be located on the first metal layer 151. The TIM layer 170 may include one or more layers. In at least one embodiment, a center of the TIM layer 170 may be substantially aligned with a center of the interposer module 120 and a center of the first metal layer 151. In at least one embodiment, the TIM layer 170 may extend laterally (e.g., in the x-y plane) beyond the outer sidewall of the first metal layer 151 and beyond the outer sidewall 127a of the molding material layer 127.

The TIM layer 170 may have a low bulk thermal impedance and high thermal conductivity. The TIM layer 170 may cover an entire area of the upper surface of the first metal layer 151. The TIM layer 170 may be attached to the upper surface of the first metal layer 151 by a thermally conductive adhesive.

In at least one embodiment, the TIM layer 170 may include one or more metals. The TIM layer 170 may include, for example, a low-melting-temperature (LMT) metal TIM or liquid metal TIM. The TIM layer 170 may include one or more metals such as indium, tin, gallium, silver, etc. The TIM layer 170 may include, for example, a gallium base, indium base, silver base, solder base, etc. The solder base may include tin and one or more other elements such as copper, silver, bismuth, indium, zinc, antimony, etc. Other metals in the TIM layer 170 are within the contemplated scope of this disclosure.

The TIM layer 170 may alternatively or additionally include a thermal grease, a thermal paste, thermal film, thermal adhesive, thermal gap filler, thermal pad (e.g., silicone), thermal tape or a gel-type TIM (e.g., a cross-linked polymer film). In at least one embodiment, the TIM layer 170 may include graphite, carbon nanotubes (CNTs), phase-change material (PCM), etc. The PCM may include, for example, a polymer based PCM. In at least one embodiment, the PCM may change its phase from solid to high-viscosity semi liquid around 60° C. Other materials in the TIM layer 170 are within the contemplated scope of this disclosure.

The second metal layer 152 may be located on the upper surface of the TIM layer 170. The second metal layer 152 may contact an entirety of the upper surface of the TIM layer 170. The second metal layer 152 may extend laterally (e.g., in the x-y plane) beyond a sidewall of the TIM layer 170 around an entire periphery of the TIM layer 170.

The material of the second metal layer 152 may be substantially the same as the material of the first metal layer 151. The second metal layer 152 may include a Cu (111) layer. Other materials such as silver, graphite, etc. may alternatively or additionally be included in the second metal layer 152.

The second metal layer 152 may also have a textured structure (e.g., a Cu (111) layer). An interaction (e.g., reaction) between the second metal layer 152 and the TIM layer 170 may cause the formation of an upper IMC layer 192 at an interface between the second metal layer 152 and the TIM layer 170. The upper IMC layer 192 may be bounded, for example, by a surface 152s of the second metal layer 152 and an upper surface 170s-2 of the TIM layer 170.

The textured structure of the second metal layer 152 may provide several advantages and benefits to the package structure 100. In particular, the second metal layer 152 may inhibit an interdiffusion of the metallization (e.g., copper) and the TIM layer 170 (e.g., metal TIM layer). The second metal layer 152 may, therefore, inhibit the formation of the upper IMC layer 192 at the interface between the second metal layer 152 and the TIM layer 170 resulting in fewer Kirkendall voids at the interface. The second metal layer 152 may result in fewer Kirkendall voids by reducing a thickness of the upper IMC layer 192 formed at the interface.

In addition, the second metal layer 152 (e.g., Cu (111) layer) may have a high thermal conductivity. In at least one embodiment, the second metal layer 152 may have a thermal conductivity of 390 W/(m·K) or more. The second metal layer 152 (e.g., highly textured Cu (111)) may, therefore, be used to improve heat dissipation efficiency in the package structure 100.

As further illustrated in FIG. 1A, the package lid 130 may be located on the TIM layer 170 and may provide a cover for the interposer module 120. The package lid 130 may be formed, for example, of metal, ceramic or polymer material. Other suitable materials of the package lid 130 may be used.

The package lid foot portion 130a of the package lid 130 may be attached to the package substrate 110. The package lid foot portion 130a may extend in a substantially perpendicular direction from the package lid plate portion 130p. The package lid foot portion 130a may be connected to the package substrate 110 by an adhesive layer 160. The adhesive layer 160 may include, for example, epoxy adhesive or silicone adhesive. Other adhesives are within the contemplated scope of this disclosure.

The package lid plate portion 130p (e.g., main body of the package lid 130) may be connected to the package lid foot portion 130a (e.g., an upper end of the package lid foot portion 130a). In at least one embodiment, the package lid plate portion 130p may be integrally formed as a unit with the package lid foot portion 130a. The package lid plate portion 130p may alternatively be formed separate from the package lid foot portion 130a and attached to the package lid foot portion 130a by an adhesive (not shown). The adhesive may be substantially similar to the adhesive layer 160 described above.

The package lid plate portion 130p may have a plate-shape extending, for example, in an x-y plane in FIG. 1A. An outer periphery of the package lid plate portion 130p may be substantially aligned with an outer periphery of the package lid foot portion 130a. The package lid plate portion 130p may be substantially parallel to an upper surface of the package substrate 110. The package lid plate portion 130p may include a central region that is formed over the interposer module 120. In at least one embodiment, a center point (in the x-y plane) of the central region may be substantially aligned with the center point of the interposer module 120 and/or with the center point of the TIM layer 170.

The package lid plate portion 130p may include a bottom surface S₁₃₀ₚ. The bottom surface S₁₃₀ₚ may extend across an underside of the package lid plate portion 130p. In at least one embodiment, the bottom surface S₁₃₀ₚ may extend between the package lid foot portion 130a on one side of package structure 100 to the package lid foot portion 130a on the opposite side of the package structure 100. In at least one embodiment, the bottom surface S₁₃₀ₚ may constitute substantially the entire underside of the package lid plate portion 130p.

The bottom surface S₁₃₀ₚ of the package lid plate portion 130p may contact the second metal layer 152. In at least one embodiment, the bottom surface S130p may directly contact an entirety of the upper surface of the second metal layer 152. The second metal layer 152 may cover an entirety of the bottom surface S₁₃₀ₚ of the package lid plate portion 130p. The second metal layer 152 may be bonded to the bottom surface S₁₃₀ₚ of the package lid plate portion 130p. The second metal layer 152, the TIM layer 170 and the first metal layer 151 may be located between the bottom surface S₁₃₀ₚ of the package lid plate portion 130p and the upper surface of the interposer module 120.

Referring again to FIG. 1B, portions of the package lid plate portion 130p, second metal layer 152 and TIM layer 170 are made transparent in the top-down view of the package structure 100 in FIG. 1B for ease of understanding. In particular, an arrangement of the second metal layer 152, TIM layer 170, first metal layer 151 and interposer module 120 are illustrated in FIG. 1B.

As illustrated in the plan view of FIG. 1B, the package lid 130 may have a width W₁₃₀ and length L₁₃₀ substantially similar (e.g., slightly less) that the width and length of the package substrate 110, respectively. The package lid 130 (e.g., package lid foot portion 130a) may be formed around an entire periphery of the interposer module 120. The package lid 130 may alternatively be formed around only a portion of the interposer module 120.

An outer boundary of the second metal layer 152 may be coextensive with the bottom surface S₁₃₀ₚ of the package lid plate portion 130p. That is, an area of the second metal layer 152 may be substantially the same as an area of the bottom surface S₁₃₀ₚ of the package lid plate portion 130p. Further, an area of the TIM layer 170 may be less than the area of the second metal layer 152, but greater than an area of the first metal layer 151. An outer boundary of the first metal layer 151 may be coextensive with an outer boundary of the interposer module 120. That is, an area of the first metal layer 151 may be substantially the same as an area of the interposer module 120.

In at least one embodiment, a ratio L₁₅₁/L₁₅₂ of the length L₁₅₁ of the first metal layer 151 to the length L₁₅₂ of the second metal layer 152 may be greater than or equal to zero. A ratio L₁₇₀/L₁₅₂ of the length L₁₇₀ of the TIM layer 170 to the length L₁₅₂ of the second metal layer 152 may be less than or equal to one (1) and greater than or equal to the ratio L₁₅₁/L₁₅₂ (e.g., 1≥L₁₇₀/L₁₅₂≥L₁₅₁/L₁₅₂≥0).

In at least one embodiment, a ratio W₁₅₁/W₁₅₂ of the width W₁₅₁ of the first metal layer 151 to the width W₁₅₂ of the second metal layer 152 may be greater than or equal to zero. A ratio W₁₇₀/W₁₅₂ of the width W₁₇₀ of the TIM layer 170 to the width W₁₅₂ of the second metal layer 152 may be less than or equal to one (1) and greater than or equal to the ratio W₁₅₁/W₁₅₂ (e.g., 1≥W₁₇₀/W₁₅₂≥W₁₅₁/W₁₅₂≥0).

As further illustrated in FIG. 1B, the package substrate 110 may have a substantially rectangular shape having a length in the x-direction greater than the width in y-direction. The package substrate 110 may alternatively have a substantially square shape. Each of the package lid foot portion 130a and interposer module 120 may have an outer shape that is substantially the same as an outer shape of the package substrate 110. Other shapes of the package substrate 110, package lid 130 and interposer module 120 are within the contemplated scope of disclosure.

The interposer module 120 may be arranged in a central portion of the package substrate 110 so that a space between the interposer module 120 and the package lid foot portion 130a is substantially uniform around the perimeter of the interposer module 120. Although FIG. 1B illustrates the package structure 100 as including one (1) first die 141 and four (4) second dies 142 having a particular arrangement, the number and arrangement of the first dies 141 and second dies 142 are not limited to the number and arrangement in FIG. 1B.

The dies 140 may have a substantially rectangular shape or alternatively a substantially square shape. Other shapes of the dies 140 are within the contemplated scope disclosure. The dies 140 may have a die length in the x-direction and a die width in the y-direction greater than the die length. Although the interposer module 120 is illustrated in FIG. 1B as including two dies 140 having a particular arrangement, the number of dies 140 and the arrangement of the dies 140 is not limited to the number and arrangement in FIG. 1B.

Referring again to FIG. 1C, the lower IMC layer 191 and the upper IMC layer 192 are not shown in FIG. 1C for ease of understanding. As illustrated in FIG. 1C, the package lid plate portion 130p may have a thickness T₁₃₀ₚ, the second metal layer 152 may have a thickness T₁₅₂, the TIM layer 170 may have a thickness T₁₇₀ and the first metal layer 151 may have a thickness T₁₅₁. The thickness T₁₃₀ₚ of the package lid plate portion 130p may be substantially uniform throughout the package lid plate portion 130p.

In at least one embodiment, a ratio T₁₅₂/T₁₇₀ of the thickness T₁₅₂ of the second metal layer 152 to the thickness T₁₇₀ of the TIM layer 170 may be greater than or equal to zero. A ratio T₁₅₁/T₁₇₀ of the thickness T₁₅₁ of the first metal layer 151 of the thickness T₁₇₀ of the TIM layer 170 may be less than or equal to one (1) and greater than or equal to the ratio T₁₅₂/T₁₇₀ (e.g., 1≥T₁₅₁/T₁₇₀≥T₁₅₂/T₁₇₀≥0). In at least one embodiment, the thickness T₁₅₂ of the second metal layer 152 may be substantially equal to the thickness T₁₅₁ of the first metal layer 151.

In at least one embodiment, the thickness T₁₇₀ of the TIM layer 170 may be in a range from 50 μm to 400 μm. In at least one embodiment, the thickness T₁₅₁ of the first metal layer 151 may be at least 10% greater than the thickness T₁₅₂ of the second metal layer 152. In at least one embodiment, each of the thickness T₁₅₁ of the first metal layer 151 and the thickness T₁₅₂ of the second metal layer 152 may be less than 50% of the thickness T₁₇₀ of the TIM layer 170. In at least one embodiment, each of the thickness T₁₅₁ of the first metal layer 151 and the thickness T₁₅₂ of the second metal layer 152 may be in a range from 10 μm to 150 μm.

Referring again to FIG. 1D, the lower IMC layer 191 at the interface between the surface 151s of the first metal layer 151 and the lower surface 170s-1 of the TIM layer 170 is illustrated. It should be noted that due to a reduced thickness of the lower IMC layer 191, this interface may be substantially free of voids. The upper IMC layer 192 at the interface between the surface 152s of the second metal layer 152 and the upper surface 170s-2 of the TIM layer 170 is also illustrated. It should be noted that due to a reduced thickness of the upper IMC layer 192, this interface may also be substantially free of voids.

The surface 151s of the first metal layer 151 and the surface 152s of the second metal layer 152 may have a substantially similar configuration. In particular, in each of the surface 151s of the first metal layer 151 and the surface 152s of the second metal layer 152, the amount of columnar grain (e.g., Cu(111) or columnar copper with (111) orientation) may be greater than 95%.

In at least one embodiment, the surface 151s of the first metal layer 151 and the surface 152s of the second metal layer 152 may include a rough surface. In at least one embodiment, the surface 151s of the first metal layer 151 may have a roughness greater than a roughness of the lower surface 170s-1 of the TIM layer 170. In at least one embodiment, the surface 152s of the second metal layer 152 may have a roughness greater than a roughness of the upper surface 170s-2 of the TIM layer 170.

The TIM layer 170 may also be more deformable (e.g., softer, more malleable, etc.) than the first metal layer 151 and more deformable than the second metal layer 152. As a result, a shape of the surface 151s of the first metal layer 151 may be imparted to the lower surface 170s-1 of the TIM layer 170, and a shape of the surface 152s of the second metal layer 152 may be imparted to the upper surface 170s-2 of the TIM layer 170.

In at least one embodiment, each of the surface 151s of the first metal layer 151 and the surface 152s of the second metal layer 152 may have a roughness Rz of at least 1 μm. In at least one embodiment, the roughness of the surface 151s of the first metal layer 151 may be substantially the same as the roughness of the surface 152s of the second metal layer 152. In at least one embodiment, the surface 151s of the first metal layer 151 and the surface 152s of the second metal layer 152 may be formed by controlling one or more parameters during formation of the first metal layer 151 and the second metal layer 152. The surface 151s may additionally or alternatively be provided by other means after the formation of the first metal layer 151 and the surface 152s of the second metal layer 152. The other means may include, for example, chemical etching, grinding, stamping, etc.

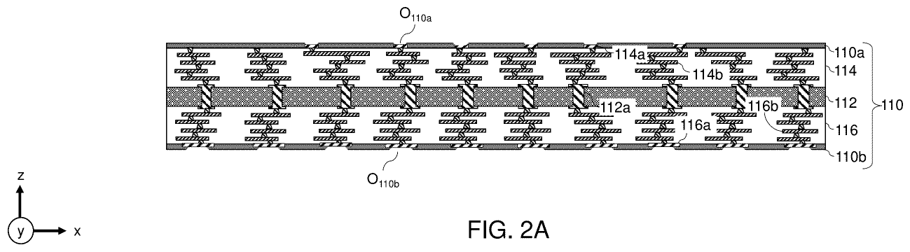

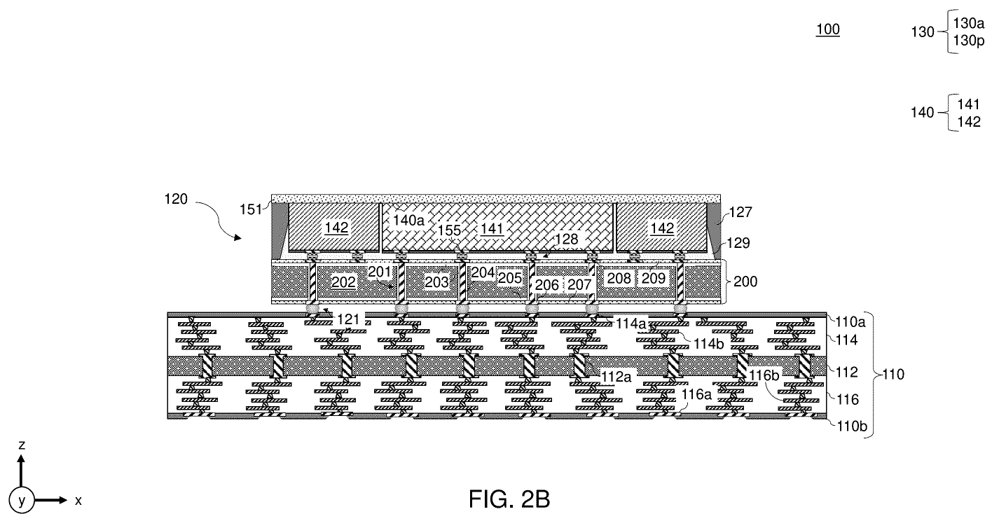

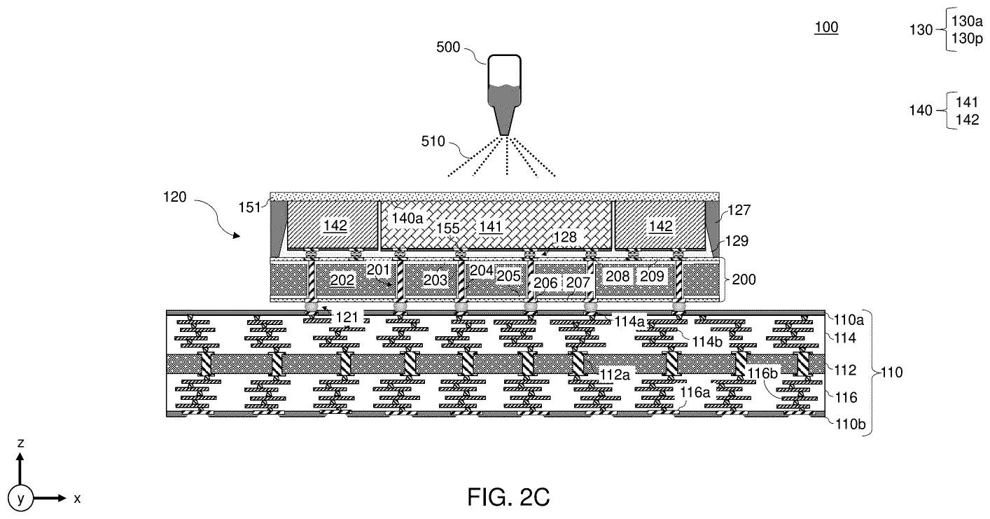

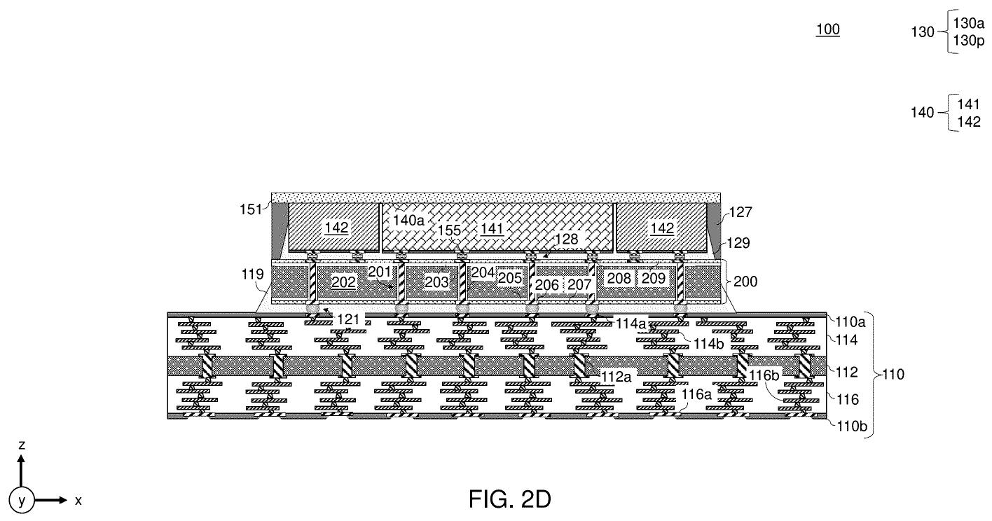

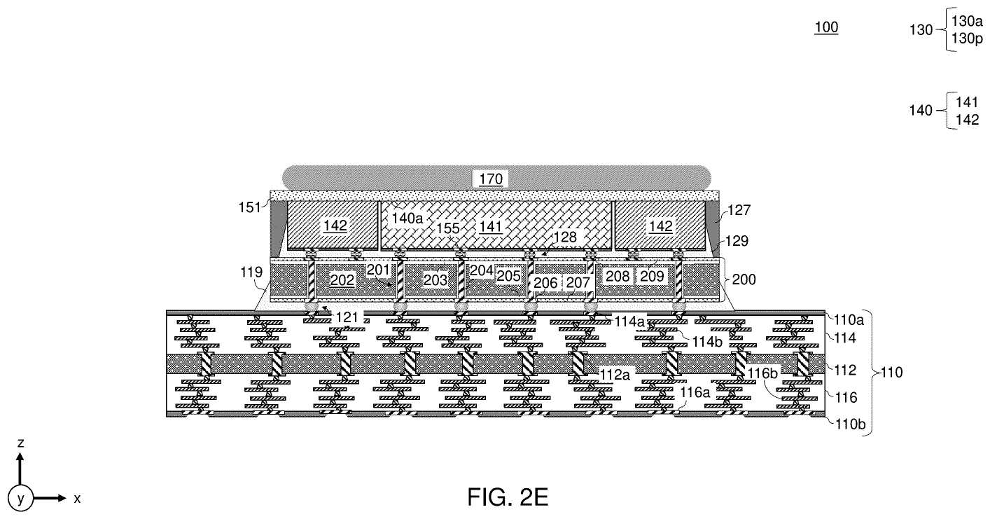

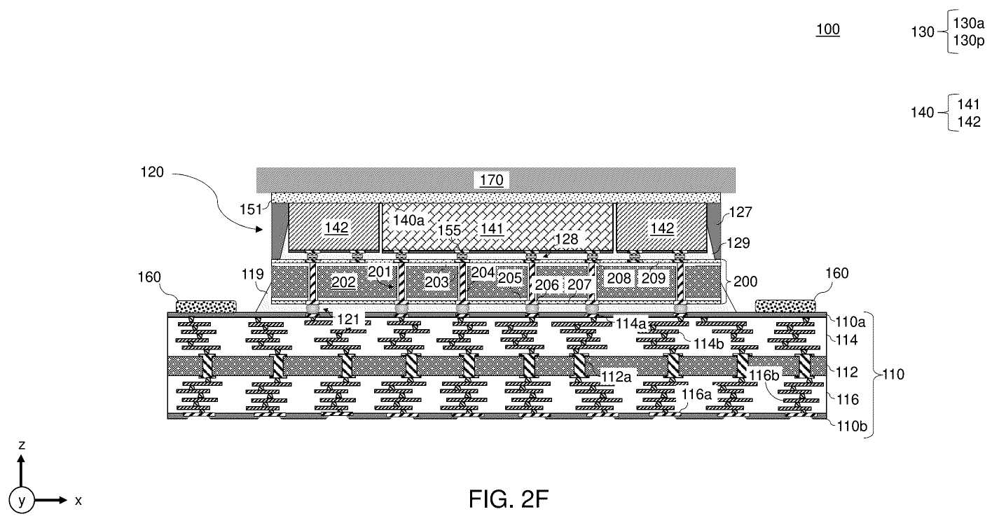

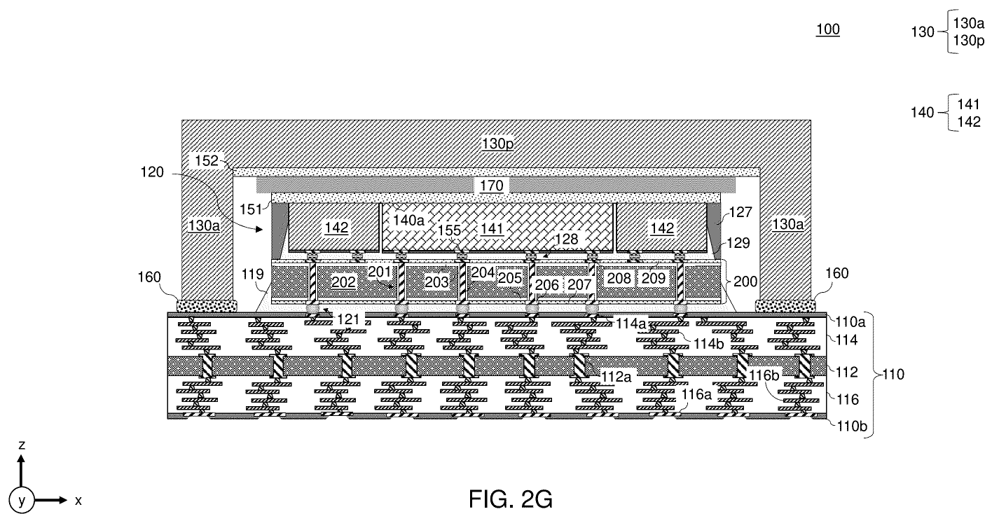

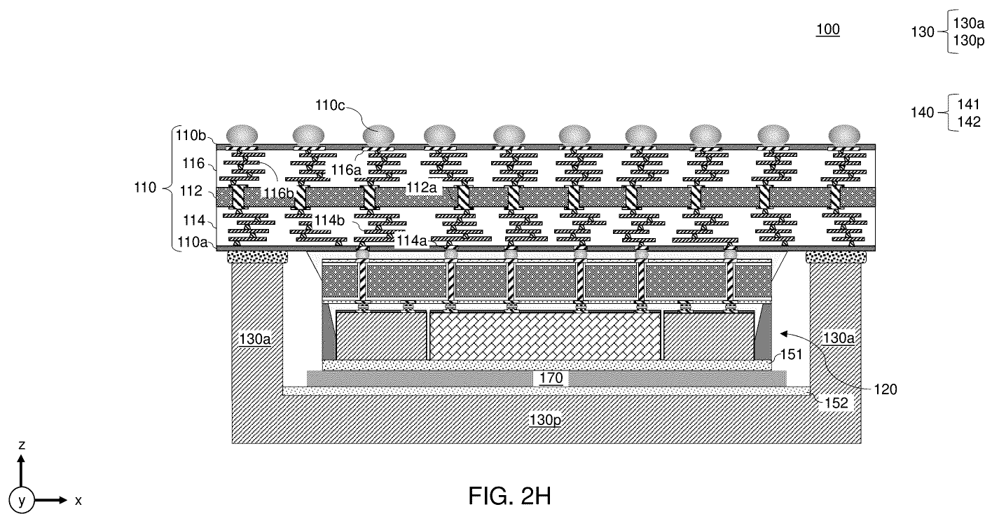

FIGS. 2A-2F illustrate various intermediate structures in a method of forming the package structure 100 according to one or more embodiments. FIG. 2A is a vertical cross-sectional view of an intermediate structure including the package substrate 110 having package substrate upper bonding pads 114a and package substrate lower bonding pads 116a, according to one or more embodiments. The package substrate 110 including the core 112, the package substrate upper dielectric layer 114, and the package substrate lower dielectric layer 116 may be provided.

The package substrate upper bonding pads 114a may be formed, for example, on an uppermost dielectric layer of the package substrate upper dielectric layer 114. The package substrate upper bonding pads 114a may be formed to contact the metal interconnect structures 114b. The package substrate upper bonding pads 114a may be formed by depositing a metal layer (e.g., copper, aluminum, or other suitable conductive materials) on the upper surface of the package substrate upper dielectric layer 114. The metal layer may then be patterned by etching (e.g., by wet etching, dry etching, etc.) to form the package substrate upper bonding pads 114a. Other suitable metal layer materials and etching processes may be within the contemplated scope of disclosure.

The package substrate lower bonding pads 116a may be formed, for example, on a lowest dielectric layer of the package substrate lower dielectric layer 116. The package substrate lower bonding pads 116a may be formed to contact the metal interconnect structures 116b. The package substrate lower bonding pads 116a may be formed in a manner similar to the manner of forming the package substrate upper bonding pads 114a (e.g., depositing a metal layer, patterning the metal layer by etching, etc.).

After formation, the package substrate upper bonding pads 114a and package substrate lower bonding pads 116a may optionally undergo a surface roughening treatment (e.g., copper zarazara (CZ) treatment). In the surface roughening treatment, a surface of the package substrate upper bonding pads 114a (e.g., a copper surface) and surface of the package substrate lower bonding pads 116a (e.g., a copper surface) may be etched by an organic acid-type microetching solution, to create a super-roughened surface (e.g., copper surface). The uniquely-roughened copper surface topography of the package substrate upper bonding pads 114a and package substrate lower bonding pads 116a may help to achieve a high copper-to-resin adhesion.

The package substrate upper passivation layer 110a and package substrate lower passivation layer 110b may then be formed on the package substrate upper bonding pads 114a and package substrate lower bonding pads 116a, respectively. In at least one embodiment, the package substrate upper passivation layer 110a and package substrate lower passivation layer 110b may each include a solder resist layer (e.g., polymer material), also referred to as a solder mask. The package substrate upper passivation layer 110a may also be referred to as the upper solder resist layer 110a, and the package substrate lower passivation layer 110b may also be referred to as the lower solder resist layer 110b.

The package substrate upper passivation layer 110a and package substrate lower passivation layer 110b may be applied concurrently. The package substrate upper passivation layer 110a and package substrate lower passivation layer 110b may be applied, for example, as a liquid photo-imageable film. The liquid photo-imageable film can be applied, for example, by silk-screening or spraying the liquid photo-imageable film onto the surface of the package substrate 110. The liquid photo-imageable film may be applied over the package substrate upper bonding pads 114a and the package substrate lower bonding pads 116a. The package substrate upper passivation layer 110a and package substrate lower passivation layer 110b may alternatively be applied as a dry-film photo-imageable film that may be vacuum-laminated onto the surface of the package substrate 110 and over the package substrate upper bonding pads 114a and package substrate lower bonding pads 116a, respectively. The package substrate upper passivation layer 110a and package substrate lower passivation layer 110b may alternatively or additionally be formed, for example, by chemical vapor deposition (CVD), physical vapor deposition (PVD), spin coating, lamination, or other suitable deposition technique.

The package substrate upper passivation layer 110a and package substrate lower passivation layer 110b may be applied to have a thickness that is slightly greater than a thickness of the package substrate upper bonding pads 114a and package substrate lower bonding pads 116a, respectively. Alternatively, the package substrate upper passivation layer 110a and package substrate lower passivation layer 110b may be applied so as to have an upper surface that is substantially coplanar with an upper surface of the package substrate upper bonding pads 114a and package substrate lower bonding pads 116a, respectively.

Openings O₁₁₀ₐ may then be formed in the package substrate upper passivation layer 110a so as to expose the upper surface of the package substrate upper bonding pads 114a. Openings O_{110b} may be formed in the package substrate lower passivation layer 110b to expose an upper surface of the package substrate lower bonding pads 116a. The openings O₁₁₀ₐ and the openings O_{110b} may be formed, for example, by using a photolithographic process. In at least one embodiment, the openings O₁₁₀ₐ and the openings O_{110b} may be formed in separate photolithographic processes.

The photolithographic process (e.g., processes) used to form the openings O₁₁₀ₐ may include forming a patterned photoresist mask (not shown) on the package substrate upper passivation layer 110a, and etching (e.g., wet etching, dry etching, etc.) the exposed upper surface of the package substrate upper passivation layer 110a through openings in the photoresist mask. The photoresist mask may be subsequently removed by ashing, dissolving the photoresist mask or by consuming the photoresist mask during the etch process.

The photolithographic process (e.g., processes) used to form the openings O_{110b} may include forming a patterned photoresist mask (not shown) on the package substrate lower passivation layer 110b, and etching (e.g., wet etching, dry etching, etc.) the exposed upper surface of the package substrate lower passivation layer 110b through openings in the photoresist mask. The photoresist mask may be subsequently removed by ashing, dissolving the photoresist mask or by consuming the photoresist mask during the etch process.

After the openings O₁₁₀ₐ are formed in the package substrate upper passivation layer 110a and the openings O_{110b} are formed in the package substrate lower passivation layer 110b, the package substrate upper passivation layer 110a (upper solder resist layer) and the package substrate lower passivation layer 110b (lower solder resist layer) may be cured such as by a thermal cure or ultraviolet (UV) cure.

FIG. 2B illustrates a vertical cross-sectional view of an intermediate structure in which the interposer module 120 may be mounted on the package substrate 110, according to one or more embodiments. The interposer module 120 may be formed, for example, in a wafer level process in which a plurality of the interposer modules 120 are formed at the same time and in the same series of steps on one wafer (e.g., silicon wafer). As part of that wafer level process, after the molding material layer 127 is formed around the dies 140 and cured, a wafer grinding step may be performed on the backside of the wafer including the molding material layer 127. The wafer grinding step may expose the upper surface 140a of the dies 140.

After the wafer grinding step, the wafer may be cleaned and polished. The first metal layer 151 may then be formed on the backside of the wafer. The first metal layer 151 may be formed, for example, by an electrochemical plating process (also known as ECP or an electroplating process). Other methods of forming the first metal layer 151 (e.g., deposition, lamination, etc.) on the interposer module 120 are within the contemplated scope of disclosure.

In the electrochemical plating process, the silicon wafer may be cleaned thoroughly to remove any contaminants or particles that could interfere with the plating process. A plating solution (e.g., electrochemical plating solution, ECP solution or electrolyte solution) containing metal ions (e.g., copper ions) is then prepared. The plating solution may allow for the transport of copper ions from the anode to the cathode (the silicon wafer) during the plating process. It usually contains a metal salt (e.g., copper salt) dissolved in a suitable solvent. The silicon wafer (the cathode) may be connected to the negative terminal of a direct current (DC) power supply. A piece of metal such as copper (e.g., the anode) may be connected to the positive terminal of the power supply. Both the cathode and anode may be submerged in the plating solution. In instances in which the power supply is turned on, metal ions (e.g., copper ions) from the plating solution may be attracted to the silicon wafer (cathode) due to the electrical potential difference. The metal ions may gain electrons at the cathode and deposit onto the silicon wafer, forming the first metal layer 151. After the desired thickness of the first metal layer 151 is achieved, the wafer may be removed from the plating solution, rinsed thoroughly to remove any residual electrolyte, and dried.

Generally, an electrochemical plating process may be used to form different types of copper including randomly arranged crystal copper, copper (111) and amorphous copper by varying the process parameters. In particular, a textured structure (e.g., the first metal layer 151) or a non-textured structure may be formed by varying process parameters such as additives, pH values of the plating solution and electrochemical plating mode (e.g., DC mode or pulse mode). For example, to form a textured structure (e.g., Cu (111)), the electrochemical plating process may utilize both DC mode and pulse mode, a small amount of additive and a plating solution with an acidic pH. Alternatively, to form a non-textured structure (e.g., Cu(100) or amorphous copper), the electrochemical plating process may utilize DC mode, a large amount of additive and a plating solution with an acidic pH.

In at least one embodiment, the electrochemical plating process used to form the first metal layer 151 may utilize a plating solution including highly purified CuSO₄, hydrochloric acid, sulfuric acid and an additive. The additive may include, for example, bis(3-sulfopropyl)disulfide (SPS), polyethylene glycol (PEG), gelatin, Janus Green B (JGB), mercaptopropyl sulfonic acid (MPS) and sodium dodecyl sulfate (SDS). The process parameters in the electrochemical plating process may be set to provide for the surface 151s on the first metal layer 151. For example, to form the surface 151s (e.g., Cu (111)), the electrochemical plating process may utilize both DC mode and pulse mode, a small amount of additive and a plating solution with an acidic pH.

The surface 151s of the first metal layer 151 may alternatively or additionally be formed by applying a surface roughening treatment (e.g., CZ treatment). In the surface roughening treatment, the surface 151s (e.g., copper surface) of the first metal layer 151 may be etched by an organic acid-type microetching solution, to create a super-roughened surface. The uniquely-roughened copper surface topography of the first metal layer 151 and the second metal layer 152 may help to achieve a high heat dissipation in the package structure 100.

After the first metal layer 151 is formed, a singulation process may be performed to separate the interposer module 120 from the wafer. First, a laser grooving step may be performed on the wafer (e.g., on the first metal layer 151). Then, a dicing saw may be used to singulate each of the individual interposer modules 120 included in the wafer.

The interposer module 120 may then be mounted on the package substrate 110, for example, by a flip chip bonding (FCB) process. The interposer module 120 may be positioned over the package substrate 110, for example, by an electromechanical pick-and-place (PNP) machine. The C4 bumps 121 (e.g., solder bumps) on the interposer module 120 may then be lowered onto the package substrate upper bonding pads 114a through the openings O₁₁₀ₐ (see FIG. 2A) in the package substrate upper passivation layer 110a. The intermediate structure including the interposer module 120 and package substrate 110 may then be heated in order to collapse the C4 bumps 121 and bond the C4 bumps 121 to the package substrate upper bonding pads 114a. In at least one embodiment, laser assisted bonding (LAB) may be used to reflow the C4 bumps 121 so that the interposer module 120 may be attached to the package substrate upper bonding pads 114a.

FIG. 2C illustrates a vertical cross-sectional view of an intermediate structure including the interposer module 120 in a flux cleaning process (e.g., flux jetting process) according to one or more embodiments. After attaching the interposer module 120 to the package substrate 110, one or more processes may be used to clean the first metal layer 151 and the package substrate 110 and maintain the surface of the first metal layer 151 and the surface of the package substrate 110. Such processes may include, for example, flux cleaning, pre-bake and plasma processes.

As illustrated in FIG. 2C, in a first flux cleaning process, a flux 510 may be applied to the intermediate structure including the interposer module 120. The flux 510 may be used to clean the upper surface of the interposer module 120 (e.g., first metal layer 151) and the upper surface of the package substrate 110. The flux 510 may help facilitate formation of a joint between the first metal layer 151 and the TIM layer 170 (e.g., a TIM layer including a metal such as indium or gallium). The flux 510 may remove impurities (e.g., oxides) from the surface of the first metal layer 151 and the upper surface of the package substrate 110. The flux 510 may also inhibit reoxidation of the first metal layer 151 during the soldering process, and reduce the surface tension and the viscosity of a metal (e.g., indium in the TIM layer 170). The flux 510 may also improve the attachment of the package underfill layer 119 that is subsequently formed on the package substrate 110.

The flux 510 may include, for example, a rosin flux, organic acid flux or inorganic acid flux. Other suitable flux materials are within the contemplated scope of this disclosure. The flux may be applied, for example, as a liquid. As illustrated in FIG. 2C, a pressurized sprayer 500 may spray the flux 510 in a liquid state onto the upper surface of the first metal layer 151 and the upper surface of the package substrate 110.

FIG. 2D illustrates a vertical cross-sectional view of an intermediate structure in which the package underfill layer 119 may be formed on the package substrate 110 according to one or more embodiments. After the cleaning process is performed, the package underfill layer 119 may be formed on the package substrate 110. The package underfill layer 119 be formed by applying a liquid material such as an epoxy-based polymeric material to the surface of the package substrate 110. As illustrated in FIG. 2C, the package underfill layer 119 may be formed (e.g., injected) under and around the interposer module 120 and the C4 bumps 121 and onto the package substrate 110. The package underfill layer 119 may then be cured, for example, in a box oven for duration in a range from 60 minutes to 120 minutes at a temperature in a range from 120° C. to 740° C. to provide the package underfill layer 119 with a sufficient stiffness and mechanical strength.

After the package underfill layer 119 is cured, a testing process (FT1) may be performed to test the intermediate structure (e.g., interposer module 120 and package substrate 110). After the testing process is completed, optional surface mounted devices (SMD) (not shown) such as DRAM devices and multilayer ceramic capacitor (MLCC) devices may be mounted on the surface of the package substrate 110 adjacent the interposer module 120. In an embodiment, a 3D stencil may be used to define which region may be covered by solder paste, and the DRAM devices and MLCC devices may be attached to the package substrate 110 by solder bumps (e.g., a reflow process). The process for attaching the DRAM devices and MLCC devices may be substantially similar as the process described above for attaching the interposer module 120 to the package substrate 110.

After the optional SMD are mounted on the package substrate 110, additional processes may be used to clean the first metal layer 151 and the package substrate 110 and maintain the surface of the first metal layer 151 and the surface of the package substrate 110. Such processes may include, for example, flux cleaning, pre-bake and plasma processes. In particular, the processes may include the flux cleaning process described above with respect to FIG. 2C.

An SMD underfill layer may then be applied to the package substrate 110 and under and around the SMD. The SMD underfill layer may include a material substantially the same as the material of the package underfill layer 119. The SMD underfill layer may also be applied and cured in a manner substantially similar to the manner of applying and curing the package underfill layer 119 described above.

After the optional SMD underfill layer is cured, the package lid 130 may be subjected to one or more pre-treatment processes for preparing the bottom surface S₁₃₀ₚ of the package lid plate portion 130p. The pre-treatment processes may include, for example, a pre-plasma process for removing impurities from the bottom surface S₁₃₀ₚ.

The second metal layer 152 may then be formed on the bottom surface S₁₃₀ₚ of the package lid plate portion 130p. The second metal layer 152 may be formed on the bottom surface S₁₃₀ₚ, for example, by a process (e.g., electrochemical plating process) similar to the process described above for forming the first metal layer 151 on the interposer module 120.

Other methods of forming the second metal layer 152 are within the contemplated scope of disclosure. It should be noted that the second metal layer 152 is not necessarily formed after the curing of the SMD underfill layer, but may be formed on the bottom surface S₁₃₀ₚ of the package lid plate portion 130p at any time prior to the attachment of the package lid 130 to the package substrate 110.

FIG. 2E illustrates a vertical cross-sectional view of an intermediate structure in which the TIM layer 170 may be formed on (e.g., attached to) the first metal layer 151 according to one or more embodiments. As illustrated in FIG. 2E, the TIM layer 170 may be applied to have a width in the x-direction and length in the y-direction that are less than the completed width and length of the TIM layer 170, since the pressing of the package lid 130 will cause a deformation of the TIM layer 170 and lateral spreading of the TIM layer 170 in the x-direction and y-direction.

In at least one embodiment, a thermally conductive adhesive may or may not be applied to the upper surface of the interposer module 120, depending upon the type of TIM layer 170 is being used. A material of the TIM layer 170 may be dispensed in the form of a liquid (e.g., grease, gel, paste, etc.) onto the upper surface of the first metal layer 151 (or onto the thermally conductive adhesive if present). In embodiments in which the TIM layer 170 includes a solid material, the TIM layer 170 may be pressed onto the first metal layer 151 or onto the adhesive if present.

After the TIM layer 170 is formed on the first metal layer 151, additional processes may be performed in preparation for attaching the package lid 130 on the package substrate. Such processes may include, for example, flux cleaning, pre-bake and plasma processes. In particular, the processes may include the flux cleaning process described above with respect to FIG. 2C.

FIG. 2F illustrates a vertical cross-sectional view of an intermediate structure in which the adhesive layer 160 may be applied to the package substrate 110 according to one or more embodiments. The adhesive layer 160 may be dispensed onto the package substrate 110 with a dispensing tool (e.g., automated dispensing tool). The dispensing tool may dispense the adhesive layer 160 in a frame shape around the interposer module 120. At the time of application, the adhesive layer 160 may be sufficiently rigid so as to form a semi-solid bead on the surface of the package substrate 110. In at least one embodiment, a viscosity of the adhesive layer 160 at the time of application may be 50,000 centipoise (cp) or greater. The shape of the semi-solid bead may remain substantially unchanged between the time of application by the dispensing tool and the later time of attaching the package lid 130. The location of the frame shape of the adhesive layer 160 may correspond to a location of the foot portion 130a of the package lid 130 (e.g., see FIG. 1B). A pressing of the package lid 130 onto the adhesive layer 160 may deform the adhesive layer 160.

FIG. 2G illustrates a vertical cross-sectional view of an intermediate structure in which the package lid 130 may be attached to (e.g., mounted on) the package substrate 110 according to one or more embodiments. After the second metal layer 152 has been formed on the package lid 130, the package lid 130 may be attached to the package substrate 110. In at least one embodiment, the package substrate 110 with the interposer module 120 may be placed on a surface. The package lid 130 may then be positioned over the package substrate 110, for example, by an electromechanical pick-and-place (PNP) machine. The package lid 130 may then be lowered down over the interposer module 120 and onto the package substrate 110. The foot portion 130a of the package lid 130 may then be aligned with the adhesive layer 160 formed on the package substrate 110.

The package lid 130 may then be pressed downward on to the TIM layer 170 by applying a pressing force down onto the package lid 130 so that the foot portion 130a of the package lid 130 may be attached to the package substrate 110 through the adhesive layer 160. The pressing force may also cause the second metal layer 152 to contact the TIM layer 170. In at least one embodiment, the pressing force may cause the second metal layer 152 and compress the TIM layer 170.

The package lid 130 may then be clamped to the package substrate 110 for a period of sufficient duration to allow the adhesive layer 160 to cure and form a secure bond between the package substrate 110 and the package lid 130. In at least one embodiment, the adhesive layer 160 is a snap-cure adhesive that may be cured by exposure to ultraviolet (UV) light.

The clamping of the package lid 130 to the package substrate 110 may additionally or alternatively be performed, for example, by using a heat clamp module. The heat clamp module may apply a uniform force across the upper surface of the package lid 130. In one or more embodiments, the heat clamp module may apply the pressing force to the package lid 130. The adhesive layer 160 may additionally or alternatively be cured, for example, in a box oven to provide the adhesive layer 160 with sufficient stiffness and mechanical strength.

FIG. 2H illustrates a vertical cross-sectional view of an intermediate structure in which a plurality of solder balls 110c may be formed on the package substrate 110 according to one or more embodiments. The plurality of solder balls 110c may be formed on the package substrate lower bonding pads 116a through the openings O_{110b} in the package substrate lower passivation layer 110b (see FIG. 2A). The solder balls 110c may be formed, for example, by an electroplating process. The solder balls 110c may be formed, for example, so as to be located under the foot portion 130a and under the interposer module 120 and therebetween. The plurality of solder balls 110c may constitute a ball-grid array (BGA) that may allow the package structure 100 to be securely mounted (e.g., by surface mount technology (SMT)) on a substrate such as a printed circuit board and electrically coupled to the substrate.

At this point, one or more optional integrated passive devices (IPDs) (e.g., passive components) may be mounted on the board-side surface of the package substrate 110. The optional IPDs may be mounted in a process similar to the mounting process for the SMD described above. In particular, the mounting process may include a solder reflow process for electrically coupling the IPDs to the package substrate 110.

After the optional IPDs are mounted on the package substrate 110, additional processes may be used to clean the package substrate 110 and maintain the surface of the package substrate 110. Such processes may include, for example, flux cleaning, pre-bake and plasma processes. In particular, the processes may include the flux cleaning process described above with respect to FIG. 2C.

An IPD underfill layer (e.g., passive component underfill) may then be applied to the package substrate 110 and under and around the IPDs. The IPD underfill layer may include a material substantially the same as the material of the package underfill layer 119. The IPD underfill layer may also be applied and cured in a manner substantially similar to the manner of applying and curing the package underfill layer 119 described above.

After the optional IPD underfill layer is cured, one or more processes may be performed prior to final testing (FT2). The processes may include, for example, one or more inspections such as an inspection by an optical inspection system (e.g., ICOS, HEXA, etc.) and a final visual inspection. These inspections may provide a sanity check (e.g., checking z-height, package appearance, etc.) of the completed package structure 100. A final testing process may then be performed on the package structure 100.

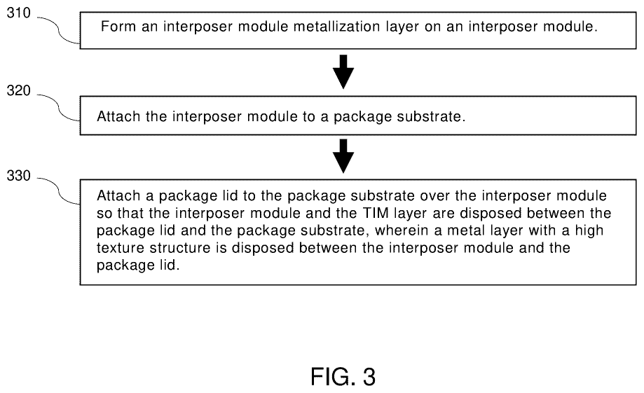

FIG. 3 is a flow chart illustrating a method of making the package structure 100 according to one or more embodiments. Step 310 includes attaching an interposer module to a package substrate. Step 320 includes forming a thermal interface material (TIM) layer on the interposer module. Step 330 includes attaching a package lid to the package substrate over the interposer module so that the interposer module and the TIM layer are disposed between the package lid and the package substrate, wherein a metal layer with a high-texture structure is disposed between the interposer module and the package lid.

The method of making the package structure 100 is not limited to the steps listed in the flowchart of FIG. 3. Further, the method illustrated in FIG. 3 is not intended to limit the method to a specific sequence of steps. For example, the formation of the second metal layer 152 on the package lid 130 in step 330 may occur at any time prior to attaching the package lid 130 to the package substrate 110. The formation of the second metal layer 152 on the package lid 130 in step 330 does not necessarily occur after the attaching of the interposer module 120 to the package substrate 110 and/or the forming of the TIM layer 170 on the first metal layer 151.

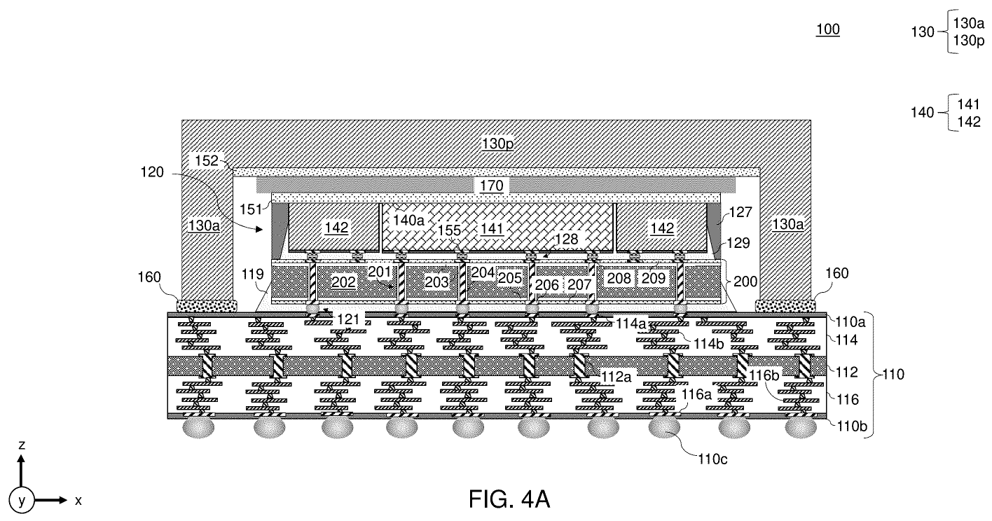

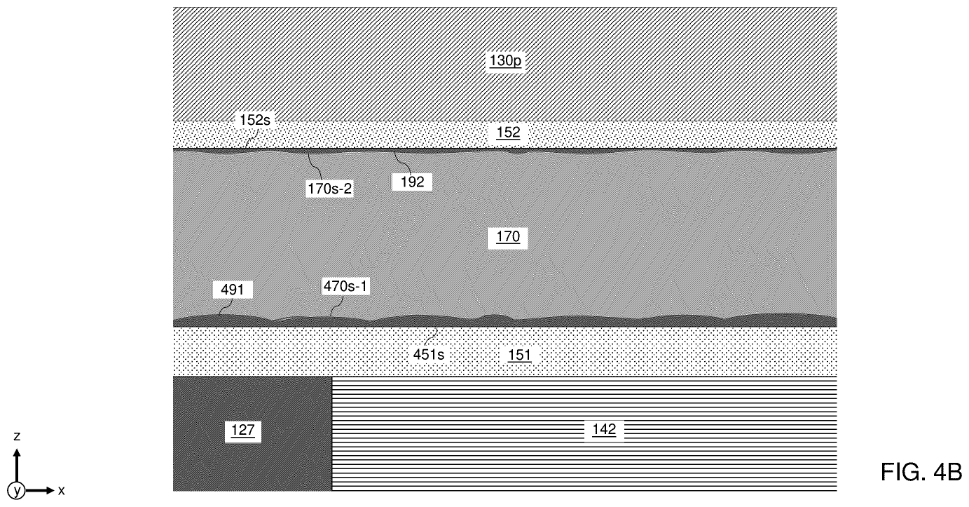

FIGS. 4A-4B are views of the package structure 100 having a first alternative design, according to one or more embodiments. In particular, FIG. 4A is a vertical cross-sectional view of the package structure 100 having the first alternative design, according to one or more embodiments. FIG. 4B is a detailed vertical cross-sectional view of a portion of the first metal layer 151 and the second metal layer 152 in the package structure 100 having the first alternative design according to one or more embodiments.

As illustrated in FIG. 4A, the first alternative design may be substantially similar to the original design in FIG. 1A and FIG. 1D. In particular, an interaction (e.g., reaction) between the second metal layer 152 (e.g., Cu (111) and the TIM layer 170 may cause the formation of an upper IMC layer 192 at an interface between the second metal layer 152 and the TIM layer 170. The upper IMC layer 192 may be bounded, for example, by a surface 152s of the second metal layer 152 and an upper surface 170s-2 of the TIM layer 170.

However, in the first alternative design, the first metal layer 151 may be different than the first metal layer 151 in the original design of FIG. 1A. As illustrated more closely in FIG. 4B, the first metal layer 151 in the first alternative design may include a non-textured metal layer having a surface 451s. In at least one embodiment, the first metal layer 151 may include Cu(100).

An interaction (e.g., reaction) between the first metal layer 151 (e.g., Cu (100) and the TIM layer 170 may cause the formation of a lower IMC layer 491 at an interface between the first metal layer 151 and the TIM layer 170. The lower IMC layer 491 may be bounded, for example, by a surface 451s of the first metal layer 151 and a lower surface 470s-1 of the TIM layer 170. As illustrated in FIG. 4B, a thickness of the lower IMC layer 491 may be greater than a thickness of the upper IMC layer 192.

In at least one embodiment, the surface 451s may be less textured than the surface 152s of the second metal layer 152. In at least one embodiment, the surface 451s may have a roughness less than a roughness of the surface 152s of the second metal layer 152. In at least one embodiment, the surface 451s may have a roughness Rz of less than 1 μm.

In at least one embodiment, the first metal layer 151 may include a Cu(111) layer. In such an embodiment, the surface 451s may include a surface of the Cu(111) layer. The surface 451s may include a significant amount of copper other than Cu(111) such as randomly arranged copper. In particular, the amount of columnar grain (e.g., Cu(111) or columnar copper with (111) orientation) in the surface 451s may be 95% or less.

The surface 451s may be provided, for example, by controlling one or more process parameters in forming the first metal layer 151. In at least one embodiment, the surface 451s may be formed by an electrochemical plating process utilizing DC mode, a large amount of additive and a plating solution with an acidic pH. The surface 451s of the first metal layer 151 may alternatively or additionally be formed by processing (e.g., by chemical mechanical polishing (CMP)) the surface 451s after formation of the first metal layer 151.

The CMP process may be applied to not only the Cu(100) layer but also the Cu(111) layer. Such process may reduce the roughness of the surface of those copper layers, and since the surface area decreases, the IMC layer formation at the surface may be inhibited, causing a thickness of the IMC layer to be reduced.

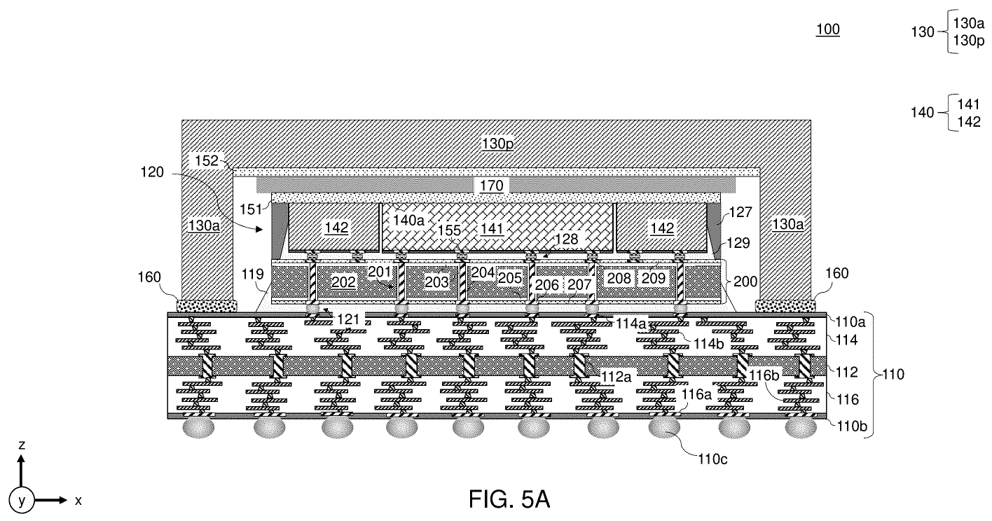

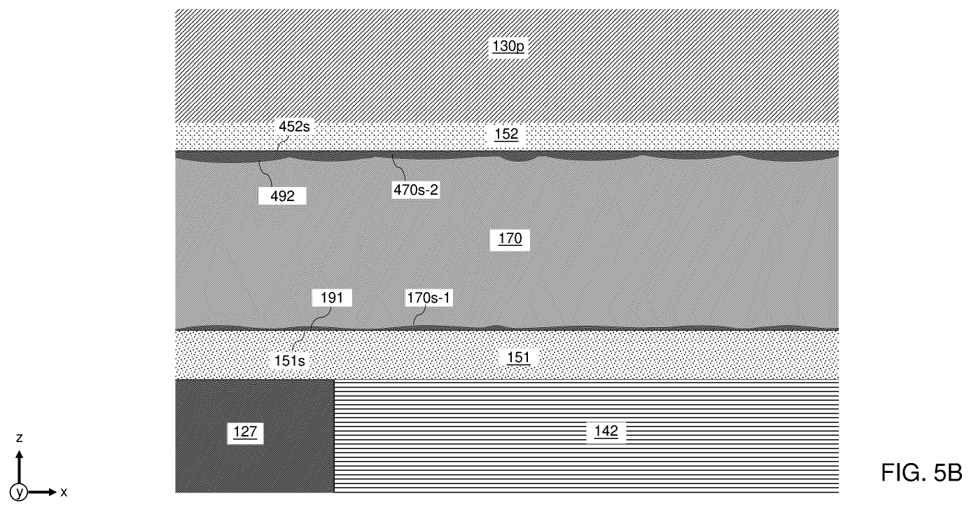

FIGS. 5A-5B are views of the package structure 100 having a second alternative design, according to one or more embodiments. In particular, FIG. 5A is a vertical cross-sectional view of the package structure 100 having the second alternative design, according to one or more embodiments. FIG. 5B is a detailed vertical cross-sectional view of a portion of the first metal layer 151 and the second metal layer 152 in the package structure 100 having the second alternative design according to one or more embodiments.

As illustrated in FIG. 5A, the second alternative design may be substantially similar to the original design in FIG. 1A. In particular, an interaction (e.g., reaction) between the first metal layer 151 (e.g., Cu (111) and the TIM layer 170 may cause the formation of a lower IMC layer 191 at an interface between the first metal layer 151 and the TIM layer 170. The lower IMC layer 191 may be bounded, for example, by a surface 151s of the first metal layer 151 and a lower surface 170s-1 of the TIM layer 170.

However, in the second alternative design, the second metal layer 152 may be different than the second metal layer 152 in the original design of FIG. 1A. As illustrated more closely in FIG. 5B, the second metal layer 152 in the second alternative design may include a non-textured metal layer having a surface 452s. In at least one embodiment, the second metal layer 152 may include Cu(100).

An interaction (e.g., reaction) between the second metal layer 152 (e.g., Cu (100) and the TIM layer 170 may cause the formation of an upper IMC layer 492 at an interface between the second metal layer 152 and the TIM layer 170. The upper IMC layer 492 may be bounded, for example, by a surface 452s of the second metal layer 152 and an upper surface 470s-2 of the TIM layer 170. As illustrated in FIG. 5B, a thickness of the upper IMC layer 492 may be greater than a thickness of the lower IMC layer 191.

In at least one embodiment, the surface 452s may be less textured than the surface 151s of the first metal layer 151. In at least one embodiment, the surface 452s may have a roughness less than a roughness of the surface 151s of the first metal layer 151. In at least one embodiment, the surface 452s may have a roughness Rz of less than 1 μm.

In at least one embodiment, the second metal layer 152 may include a Cu(111) layer. In such an embodiment, the surface 452s may include a non-textured structure of the Cu(111) layer. The surface 452s may include a significant amount of copper other than Cu(111) such as randomly arranged copper. In particular, the amount of columnar grain (e.g., Cu(111) or columnar copper with (111) orientation) in the surface 452s may be 95% or less.

The surface 452s may be provided, for example, by controlling one or more process parameter in forming the second metal layer 152. In at least one embodiment, the surface 452s may be formed by an electrochemical plating process utilizing DC mode, a large amount of additive and a plating solution with an acidic pH. The surface 452s of the second metal layer 152 may alternatively or additionally be formed by processing (e.g., by chemical mechanical polishing (CMP)) the surface 452s after formation of the second metal layer 152.

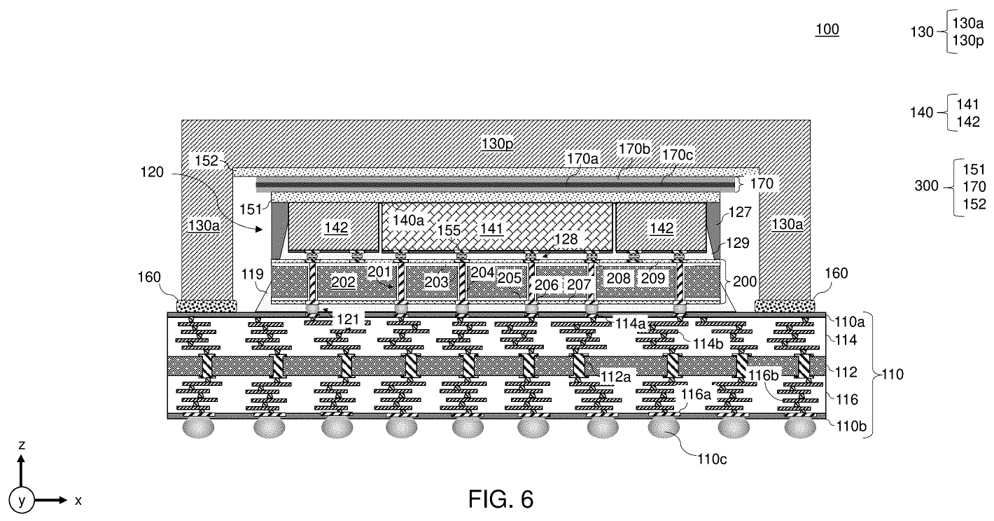

FIG. 6 is a vertical cross-sectional view of the package structure 100 having the third alternative design, according to one or more embodiments. As illustrated in FIG. 6, the third alternative design may be substantially similar to the original design in FIG. 1A. However, in the third alternative design, the TIM layer 170 may be different than the TIM layer 170 in the original design of FIG. 1A.

In particular, the TIM layer 170 in the third alternative design may include a hybrid TIM layer. The TIM layer 170 in the third alternative design may also be referred to as hybrid TIM layer 170. The hybrid TIM layer 170 may include a first TIM layer 170a adjacent the first metal layer 151 and a second TIM layer 170b adjacent the second metal layer 152. The hybrid TIM layer 170 may also include an inner TIM layer 170c between the first TIM layer 170a and the second TIM layer 170b. The inner TIM layer 170c may have a thermal conductivity greater than the thermal conductivity of the first TIM layer and greater than the thermal conductivity of the second TIM layer. In at least one embodiment, first TIM layer 170a and the second TIM layer 170c may each include a metal TIM layer including indium, tin, gallium, silver, etc. The inner TIM layer 170c may include, for example, a graphite film.

In at least one embodiment, a length in the x-direction and width in the y-direction of each of the first TIM layer 170a, second TIM layer 170b and inner TIM layer 170c may be substantially the same. In at least one embodiment, a thickness of the first TIM layer 170a may be substantially the same as a thickness of the second TIM layer 170b. In at least one embodiment, a thickness of the inner TIM layer 170c may be less than the thickness of the first TIM layer 170a and less than the thickness of the second TIM layer 170b. In at least one embodiment, a thickness of the inner TIM layer 170c may be less than 50% of the overall thickness of the hybrid TIM layer 170.

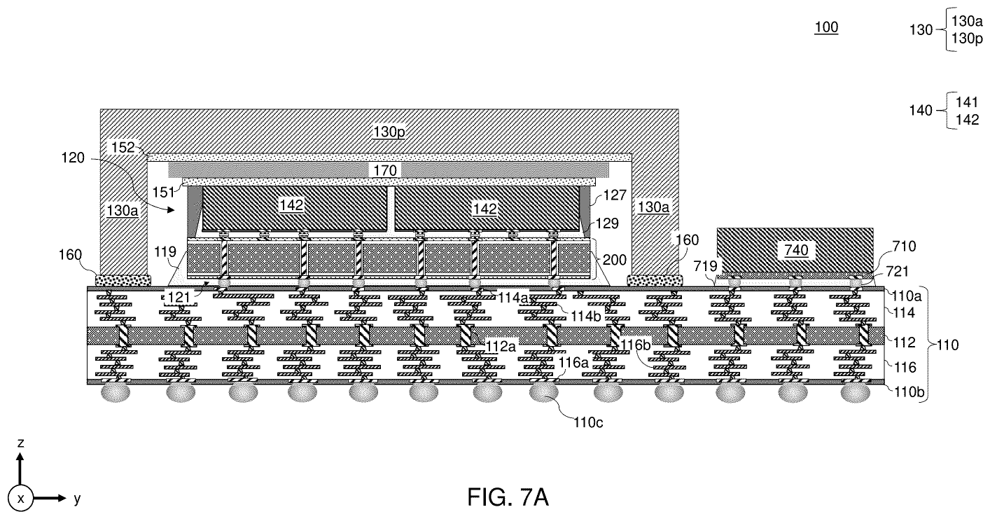

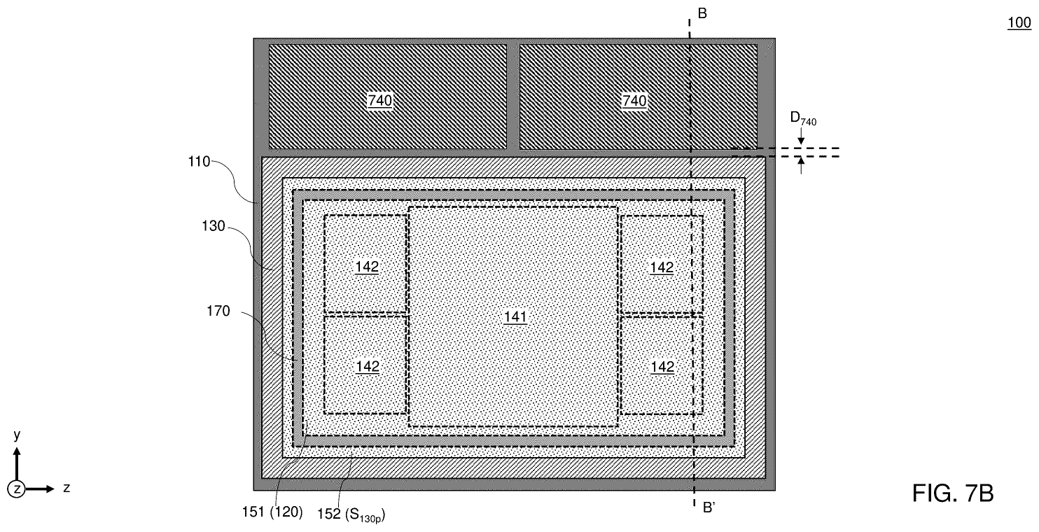

FIGS. 7A-7B are views of the package structure 100 having a fourth alternative design, according to one or more embodiments. In particular, FIG. 7A is a vertical cross-sectional view of the package structure 100 having the fourth alternative design, according to one or more embodiments. FIG. 7B is a plan view (e.g., top-down view) of the package structure 100 having a fourth alternative design according to one or more embodiments. The vertical cross-sectional view in FIG. 7A is along the line b-B′ in FIG. 1B.

As illustrated in FIG. 7A, in the fourth alternative design, the package structure 100 may include one or more SMDs 740 on the chip-side surface of the package substrate 110 adjacent the package lid 130. The SMDs 740 may include, for example, a semiconductor die such as the dies 140 described above. In at least one embodiment, the SMDs 740 may include a memory die such as a DRAM die, HBM die, etc. The SMDs 740 may be electrically coupled to the interposer module 120 (and the dies 140 in the interposer module 120) through the package substrate 110. The SMDs 740 may also include non-functional dies (e.g., dummy dies) that may provide structural support to the package structure 100.

The SMDs 740 may also include, for example, an MLCC device, integrated circuits, passive components such as resistors, capacitors and inductors, active components such as two-terminal devices, diodes and three-terminal devices, and electromechanical devices such as switches/relays, connectors and micro-motors. In at least one embodiment the SMDs 740 may include transistors (e.g., metal oxide semiconductor field effect transistors (MOSFETs)), rectifiers and voltage regulators for power management applications.

The SMDs 740 may be attached to the package substrate 110 by surface mount technology (SMT). As with the interposer module 120, the SMDs 740 may be mounted on the package substrate upper bonding pads 114a. The SMDs 740 may therefore be electrically connected to the metal interconnect structures 114b in the package substrate upper dielectric layer 114. The SMDs 740 may, therefore, be electrically coupled to the semiconductor dies 140 through the package substrate 110 and the interposer 200.

The SMDs 740 may include, for example, an SMD substrate 710. The SMD substrate may include, for example, an organic or inorganic substrate (e.g., silicon wafer). The SMDs 740 may be attached to the package substrate 110 by a plurality of C4 bumps 721. The C4 bumps 721 may have a structure and function substantially similar to the structure and function of the C4 bumps 121 described above. Similar to the C4 bumps 121, the C4 bumps 721 may be bonded the package substrate upper bonding pads 114a, respectively. The SMDs 740 may be electrically coupled to the package substrate 110 through the C4 bumps 721. Other suitable means of attaching the SMDs 740 to the package substrate 110 (e.g., adhesive) may be used.

An SMD underfill layer 719 may be formed on the package substrate 110, under and around the SMDs 740, and around the C4 bumps 721. The SMD underfill layer 719 may help to securely fix the SMDs 740 to the package substrate 110. The SMD underfill layer 719 may be substantially the same as the package underfill layer 129 described above. In particular, the SMD underfill layer 719 may be formed of an epoxy-based polymeric material.

As illustrated in FIG. 7B, the SMDs 740 may be located on a longitudinal side of the package lid 130. It should be noted that the SMDs 740 may have other locations on the package substrate 110 (e.g., located on a short side of the package lid 130). The package substrate 110 may have a substantially square shape that accommodates the package lid 130 and the SMDs 740. A length of the SMDs 740 in the y-direction may be less than the width W₁₃₀ of the package lid 130 (see FIG. 1B). Each of the SMDs 740 may have a size (e.g., area in the plan view) that is less than a size of the interposer module 120. In at least one embodiment, a distance D₇₄₀ between the SMDs 740 and the package lid 130 may be less than 1000 μm.

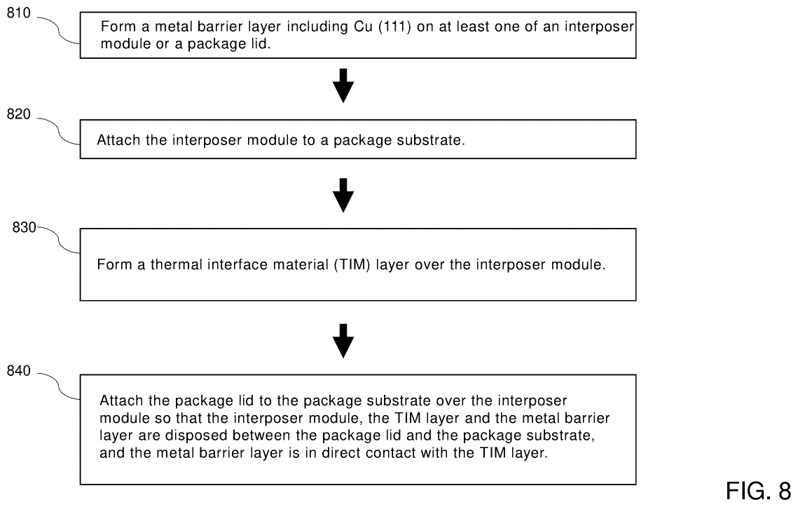

FIG. 8 is a flow chart illustrating an alternative method of making the package structure 100 according to one or more embodiments. Step 810 includes forming a metal layer including Cu (111) on at least one of an interposer module or a package lid. Step 820 includes attaching the interposer module to a package substrate. Step 830 includes forming a thermal interface material (TIM) layer over the interposer module. Step 840 includes attaching the package lid to the package substrate over the interposer module so that the interposer module, the TIM layer and the metal layer are disposed between the package lid and the package substrate, and the metal layer is in direct contact with the TIM layer.

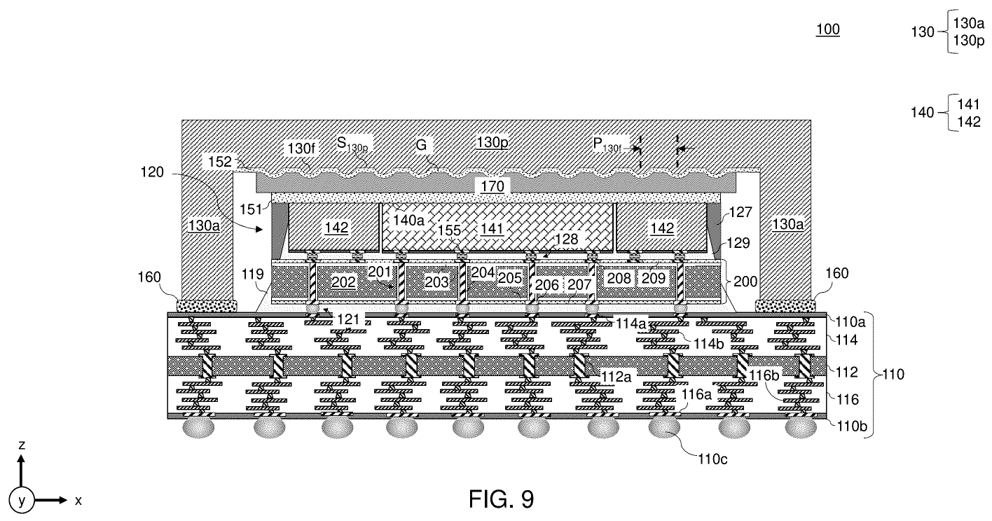

FIG. 9 is a vertical cross-sectional view of the package structure 100 having a fifth alternative design, according to one or more embodiments. As illustrated in FIG. 9, in the fifth alternative design, the package lid 130 may include a plurality of fins 130f extending from the package lid plate portion 130p into the TIM layer 170 over the interposer module 120. The second metal layer 152 may be formed on the plurality of fins 130f. The plurality of fins 130f may form an innovative fin heat spreader in the package structure 100.

As illustrated in FIG. 9, the plurality of fins 130f may extend from the bottom surface S₁₃₀ₚ of the package lid plate portion 130p into the TIM layer 170 over the interposer module 120. The plurality of fins 130f may enhance the dissipation of heat in the package structure 100 while also enhancing a mechanical structure of the TIM layer 170. The fins 130f may be separated, for example, by a gap G and at least a portion of the TIM layer 170 may be located in the gap G. In at least one embodiment, each of the fins 130f may be located over the interposer module 120. In at least one embodiment, the fins 130f may be located over the dies 140 in the interposer module 120. In at least one embodiment, each of the fins 130f may extend to some extent into the TIM layer 170.

The fins 130f of the package lid 130 may extend in the form of a cylinder from the bottom surface S₁₃₀ₚ of the package lid plate portion. The fins 130f may be formed as a circular cylinder in which case the fins 130f may have a circular-shaped cross-section. An arc-shaped end portion of the fins 130f may be formed within the TIM layer 170. The fins 130f may alternatively be formed as a square cylinder in which case the fins 130f may have a square-shaped cross-section. Other shapes of the fins 130f are within the contemplated scope of disclosure. For example, oval-shaped cross section, triangular-shaped cross section as well as other polygon-shaped cross sections may be used.

The fins 130f of the package lid 130 may have a pitch P_{130f} (e.g., distance between centers) in both the x-direction and in the y-direction. The fins 130f of the package lid 130 may alternatively have a pitch in the x-direction different from the pitch in the y-direction. In at least one embodiment, the pitch P_{130f} may be in a range from 1 mm to 5 mm. The pitch P_{130f} may be substantially uniform throughout the entirety of the fins 130f. The pitch P_{130f} may alternatively vary among the fins 130f in the x-direction and/or y-direction. Put another way, the pitch P_{130f} in the x-direction may be the same or different than the pitch P_{130f} in the y-direction.

The fins 130f of the package lid 130 may be formed over the dies 140 in the interposer module 120. In at least one embodiment, a position of the fins 130f may correspond to a semiconductor (e.g., silicon) region of the interposer module 120 (e.g., a die region, system on chip region, HBM region, etc.). In at least one embodiment, one or more of the fins 130f may include at least a portion over the molding material layer 127 in the interposer module 120. In at least one embodiment, the fins 130f may be formed in an array of rows and columns on the dies 140.

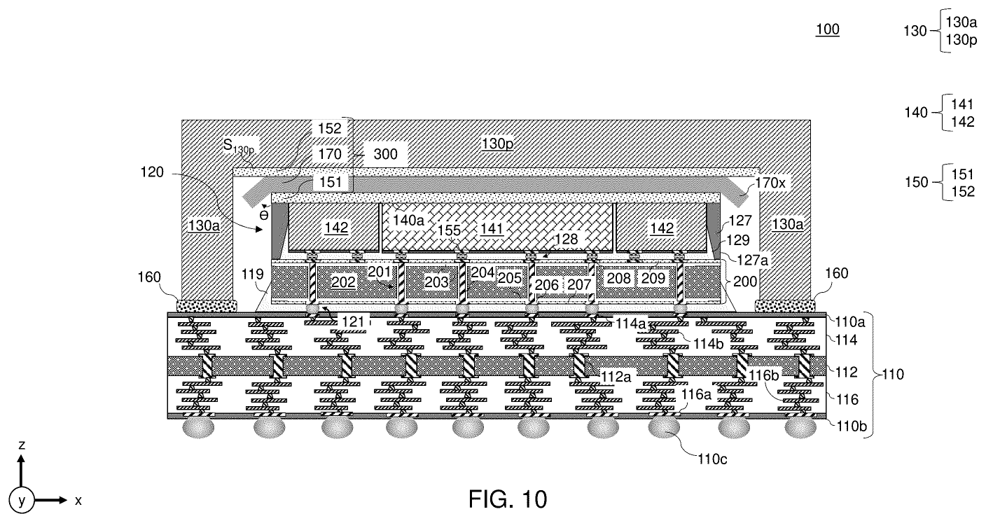

FIG. 10 is a vertical cross-sectional view of the package structure 100 having a sixth alternative design, according to one or more embodiments. As illustrated in FIG. 10, in the sixth alternative design, the TIM layer 170 may include a TIM layer extension portion 170x located outside the interposer module 120. In at least one embodiment, the TIM layer extension portion 170x may be formed around an entire periphery of the interposer module 120. The TIM layer extension portion 170x may help to facilitate heat dissipation in the package structure 100.

The TIM layer extension portion 170x may be formed of the same materials as the rest of the TIM layer 170 (e.g., the portion of the TIM layer 170 between the interposer module 120 and the package lid plate portion 130p). The TIM layer extension portion 170x may be integrally formed with the rest of the TIM layer 170. The TIM layer extension portion 170x may be formed concurrently with the forming of the rest of the TIM layer 170 and using the same process as the process used in forming of the rest of the TIM layer 170. The TIM layer extension portion 170x may have a thickness substantially similar to a thickness of the rest of the TIM layer 170.

As illustrated in FIG. 10, in the sixth alternative design, the TIM layer extension portion 170x may project outwardly and downwardly from the rest of the TIM layer 170 (e.g., from an end of the TIM layer 170 in the original design in FIG. 1A). The TIM layer extension portion 170x may project downwardly at an angle θ with respect to the outer sidewall 127a of the molding material layer 127 and with respect to an outer sidewall of the first metal layer 151. The TIM layer extension portion 170x may not contact the first metal layer 151 or an inner sidewall of the foot portion 130a. In at least one embodiment, the angle θ may be less than 90° between the bottom surface of the TIM layer extension portion 170x and the outer sidewall 127a of the molding material layer 127 (e.g., between the bottom surface of the TIM layer extension portion 170x and the outer sidewall of the first metal layer 151).

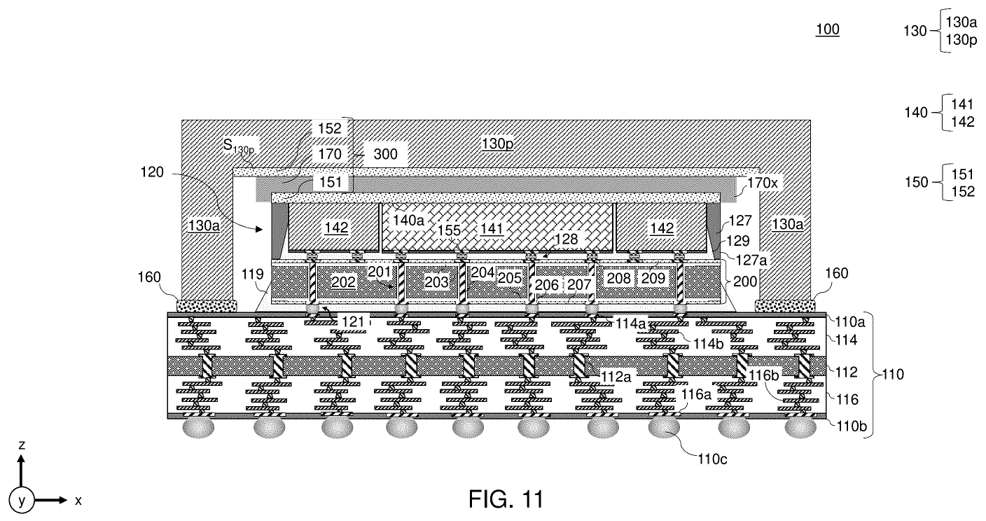

FIG. 11 is a vertical cross-sectional view of the package structure 100 having a seventh alternative design, according to one or more embodiments. The seventh alternative design may be substantially similar to the sixth alternative design described above with respect to FIG. 10. For example, the TIM layer 170 may include the TIM layer extension portion 170x located outside the interposer module 120, the TIM layer extension portion 170x may be formed around an entire periphery of the interposer module 120, and so on.

However, the TIM layer extension portion 170x in the seventh alternative design may differ from the TIM layer extension portion 170x in the sixth alternative design in terms of the projecting direction of the TIM layer extension portion 170x. In particular, in the seventh alternative design, the TIM layer extension portion 170x may project downwardly in a direction along the sidewall of the interposer module 120 (e.g., along the outer sidewall 127a of the molding material layer 127) toward the package substrate 110. A length of the TIM layer extension portion 170x may be such that height of an end of the TIM layer extension portion 170x may be about the same as a height of the uppermost surface of the molding material layer 127. The TIM layer extension portion 170x may contact a sidewall of the first metal layer 151. In at least one embodiment, the TIM layer extension portion 170x may contact the outer sidewall 127a of the molding material layer 127.

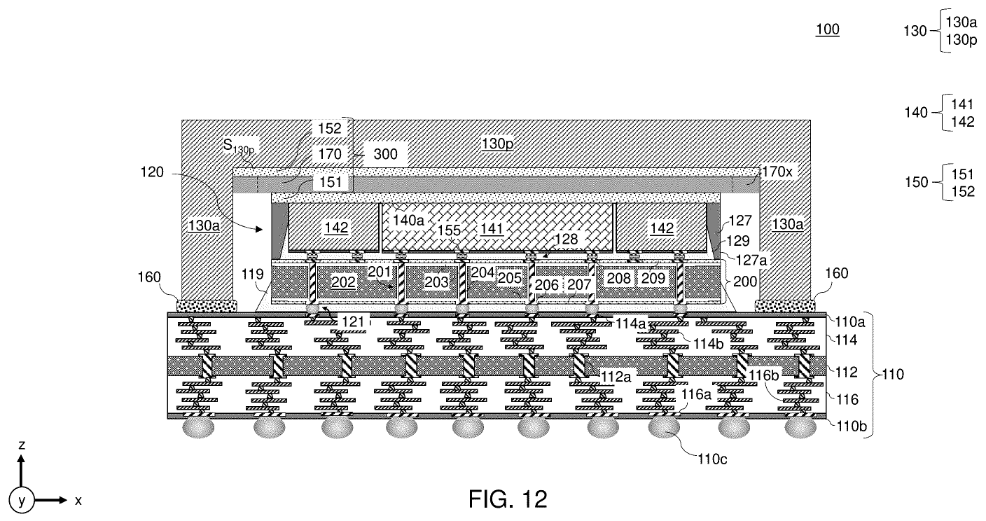

FIG. 12 is a vertical cross-sectional view of the package structure 100 having an eighth alternative design, according to one or more embodiments. The eighth alternative design may also be substantially similar to the sixth alternative design described above with respect to FIG. 10. However, the TIM layer extension portion 170x in the eighth alternative design may differ from the TIM layer extension portion 170x in the sixth alternative design in terms of the projecting direction of the TIM layer extension portion 170x. In particular, in the eighth alternative design, the TIM layer extension portion 170x may project laterally and contact an inner sidewall of the foot portion 130a of the package lid 130. That is, in the eighth alternative design, the TIM layer extension portion 170x may not project downwardly to any extent. With this design, the TIM layer extension portion 170x may be especially helpful in facilitating heat dissipation in the package structure 100.

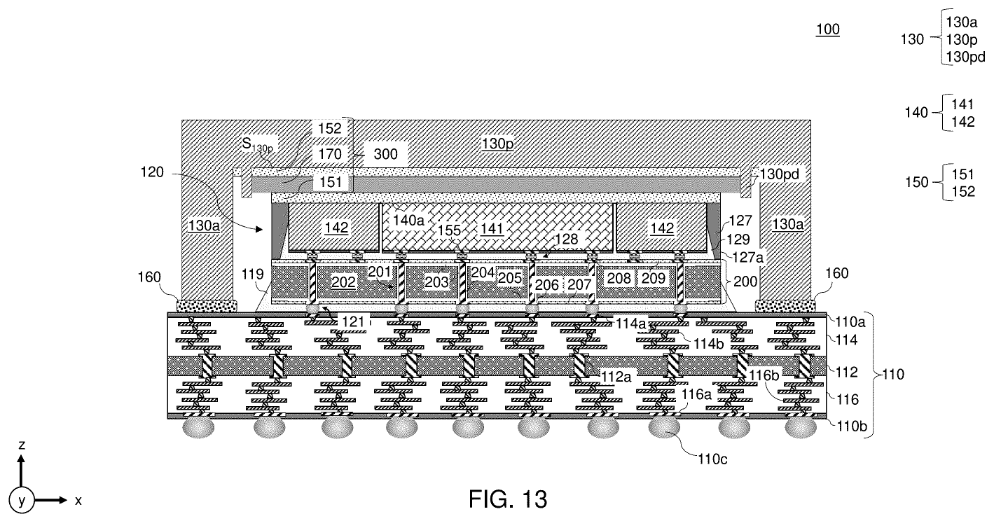

FIG. 13 is a vertical cross-sectional view of the package structure 100 having a ninth alternative design, according to one or more embodiments. As illustrated in FIG. 13, in the ninth alternative design, the package lid 130 may include a dam structure 130pd projecting from the bottom surface S₁₃₀ₚ of the plate portion 130p of the package lid 130. The dam structure 130pd may project downwardly between the TIM layer 170 and the foot portion 130a of the package lid 130. In at least one embodiment, the dam structure 130pd may project in a direction substantially parallel to an inner sidewall of the foot portion 130a. In at least one embodiment, the dam structure 130pd may be formed continuously around an entire periphery of the interposer module 120. The dam structure 130pd may help to contain a lateral spreading of the TIM layer 170. In particular, the dam structure 130pd may prevent the TIM layer 170 (especially if the TIM layer 170 includes a gel-type TIM) from dripping onto the interposer 200 or a device mounted on the interposer 200.

The dam structure 130pd may be formed of the same materials as the package lid plate portion 130p. The dam structure 130pd may be integrally formed with the package lid plate portion 130p. The dam structure 130pd may be formed concurrently with the forming of the package lid 130. For example, the dam structure 130pd may be formed by the same computer numerical control (CNC) machining process used to the form the package lid 130. The dam structure 130pd may have a width (e.g., in the x-direction) in a range of from 1 mm to 20 mm. A length of the dam structure 130pd in the z-direction may be such that a height of an end of the dam structure 130pd may be substantially the same as a height of the first metal layer 151. As illustrated in FIG. 13, an inner sidewall of the dam structure 130pd may contact the second metal layer 152 and the TIM layer 170.

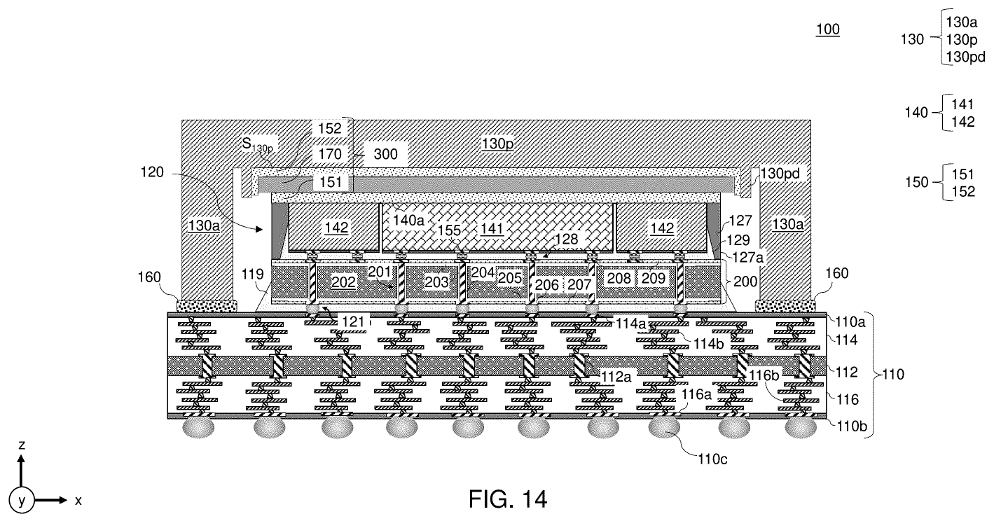

FIG. 14 is a vertical cross-sectional view of the package structure 100 having a tenth alternative design, according to one or more embodiments. As illustrated in FIG. 14, in the tenth alternative design, the package lid 130 may include a dam structure 130pd substantially similar to the dam structure 130pd in the ninth alternative design in FIG. 13. However, in contrast to the ninth alternative design, in the tenth alternative design, the second metal layer 152 (e.g., Cu(111)) may be formed along the inner sidewall of the dam structure 130pd. The second metal layer 152 may contact an end of the TIM layer 170. In at least one embodiment, the second metal layer 152 may separate the end of the TIM layer 170 from the inner sidewall of the dam structure 130pd. A length of the second metal layer 152 in the z-direction may be such that a height of an end of the second metal layer 152 may be greater than a height of the end of the dam structure 130pd. The second metal layer 152 may be formed on the inner sidewall of the dam structure 130pd by the same plating process used to form the second metal layer 152 on the package lid plate portion 130p. This design may help to enhance a heat dissipation effect while inhibiting formation of an IMC layer (e.g., between the second metal layer 152 and the TIM layer 170). A thickness of the second metal layer 152 on the inner sidewall of the dam structure 130pd may be substantially the same as a thickness of the rest of the second metal layer 152.

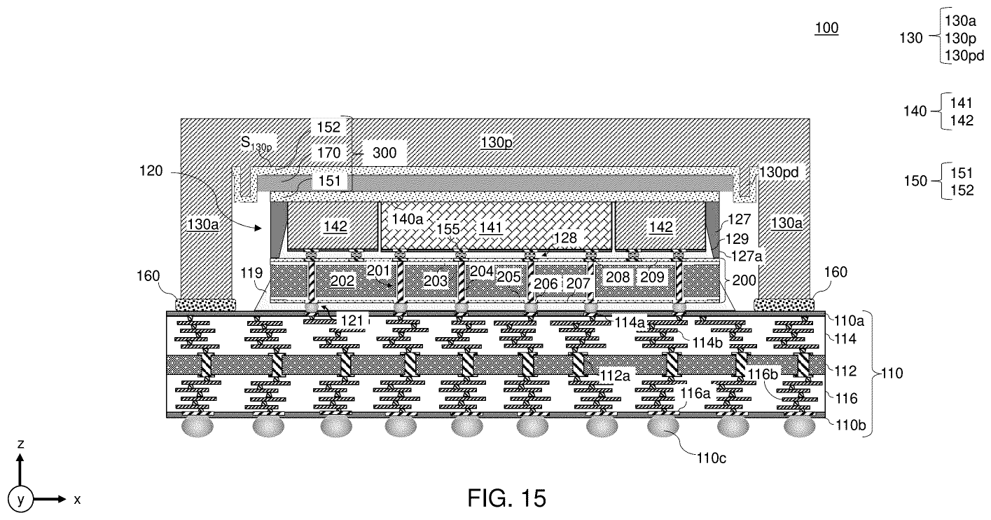

FIG. 15 is a vertical cross-sectional view of the package structure 100 having an eleventh alternative design, according to one or more embodiments. As illustrated in FIG. 15, in the eleventh alternative design, the package lid 130 may include a dam structure 130pd substantially similar to the dam structure 130pd in the ninth alternative design in FIG. 13 and the tenth alternative design in FIG. 14. However, in contrast to the ninth alternative design and tenth alternative design, in the eleventh alternative design, the second metal layer 152 (e.g., Cu(111)) may be formed over substantially the entire surface of the dam structure 130pd. The second metal layer 152 may also be formed, for example, by the same plating process used to form the second metal layer 152 on the package lid plate portion 130p. This design of the eleventh alternative design may also help to enhance a heat dissipation effect while inhibiting formation of an IMC layer (e.g., between the second metal layer 152 and the TIM layer 170).

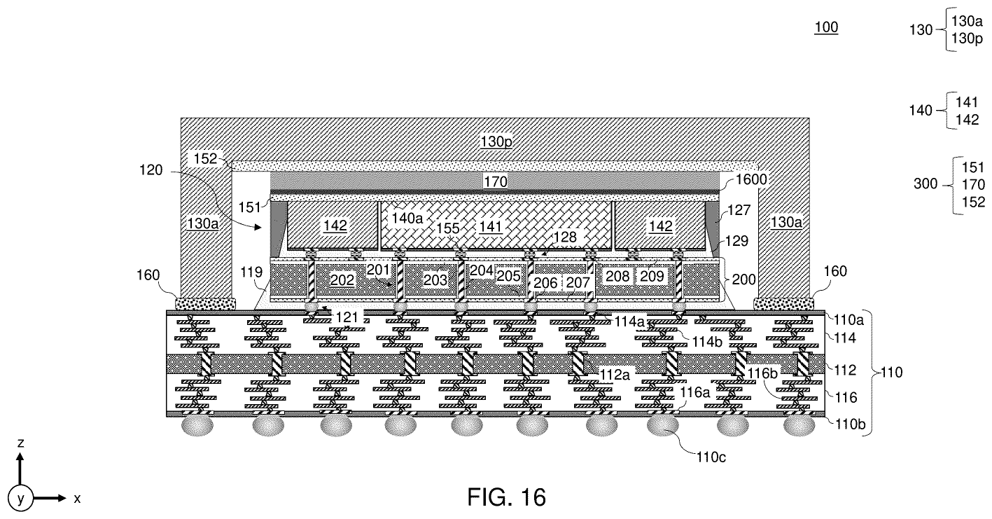

FIG. 16 is a vertical cross-sectional view of the package structure 100 having a twelfth alternative design, according to one or more embodiments. As illustrated in FIG. 16, the package structure 100 having the twelfth alternative design may be substantially similar to the package structure 100 having the third alternative design in FIG. 6. However, in the twelfth alternative design, the package structure 100 may include the TIM layer 170 (e.g., metal TIM) and a graphite film 1600 between the TIM layer 170 and the first metal layer 151 (e.g., at the bottom of the TIM layer 170).

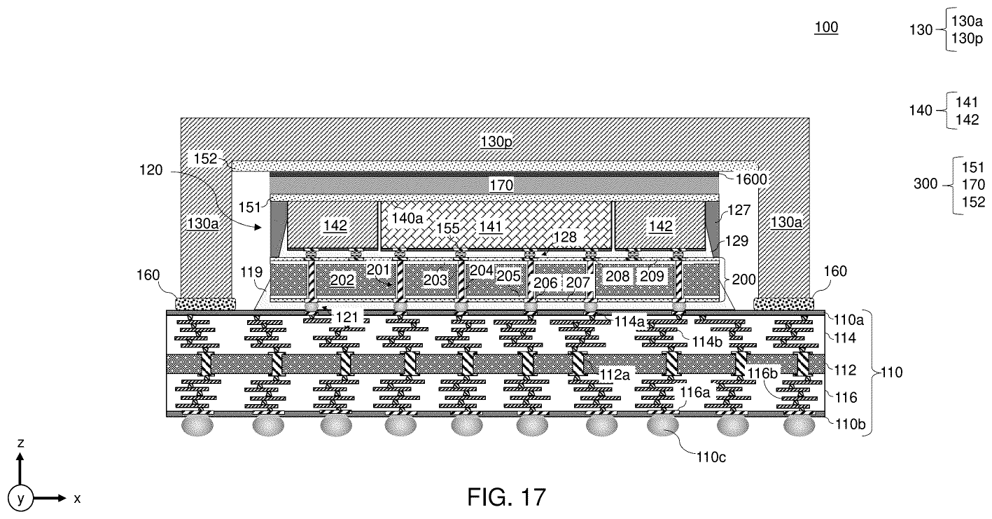

FIG. 17 is a vertical cross-sectional view of the package structure 100 having a thirteenth alternative design, according to one or more embodiments. As illustrated in FIG. 17, the package structure 100 having the thirteenth alternative design may be substantially similar to the package structure 100 having the third alternative design in FIG. 6 and the package structure 100 having the twelfth alternative design in FIG. 16. However, in the thirteenth alternative design, the package structure 100 may include the TIM layer 170 (e.g., metal TIM) and the graphite film 1600 between the TIM layer 170 and the second metal layer 152 (e.g., at the top of the TIM layer 170).

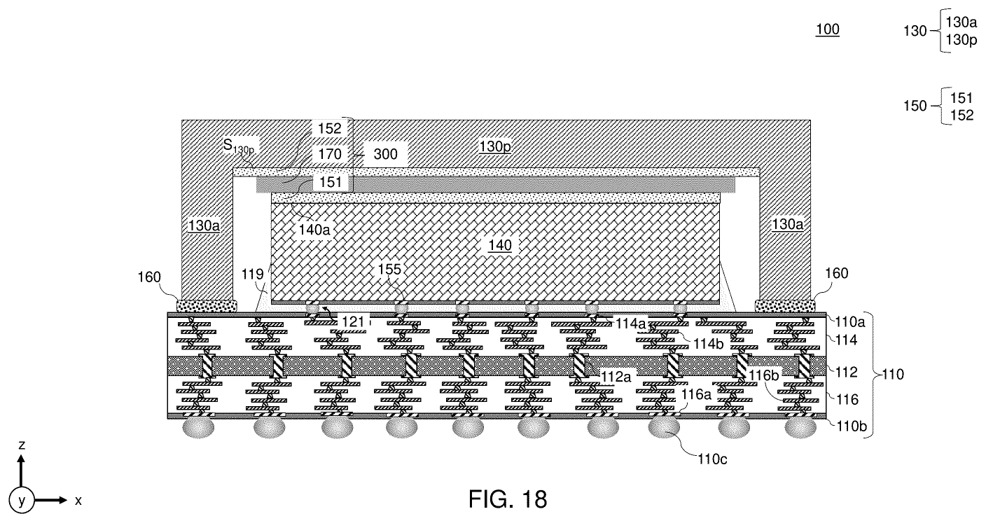

FIG. 18 is a vertical cross-sectional view of the package structure 100 having a fourteenth alternative design, according to one or more embodiments. As illustrated in FIG. 18, the package structure 100 having the fourteenth alternative design may be substantially similar to the package structure 100 in FIG. 1A. However, in the fourteenth alternative design in FIG. 18, the interposer module 120 may be replaced by one or more semiconductor dies 140 (e.g., semiconductor chips or chips). Thus, in the fourteenth alternative design, the interposer 200 may be omitted from the package structure 100 and one or more of the semiconductor dies 140 may be attached to the package substrate 110 without the use of an interposer.

As illustrated in FIG. 18, a width (in the x-direction) of the first metal layer 151 is substantially equal to a width (in the x-direction) of the semiconductor die 140. The semiconductor die 140 may be attached to the package substrate 110 by one or more C4 bumps 121. The semiconductor die 140 may alternatively or additionally be attached to the package substrate 110 by microbumps or other suitable interconnect. The semiconductor die 140 may alternatively or additionally be attached to the package substrate 110 by a hybrid bond (e.g., direct bond) or other suitable bonding method.

The package structure 100 having the fourteenth alternative design may be formed by a method substantially similar to the method described in FIGS. 2A-2H and the associated text. It should also be noted that any of the features of the other embodiments of the package structure 100 may also be implemented in the fourteenth embodiment in FIG. 18. Thus, for example, the features of the first alternative design in FIGS. 4A-4B may be implemented in the fourteenth embodiment in FIG. 18, the features of the second alternative design in FIGS. 5A-5B may be implemented in the fourteenth embodiment in FIG. 18, and so on.

Referring now to FIGS. 1A-8, a package structure 100 may include a package substrate 110, a chip 141, 142 on the package substrate 110, a package lid 130 on the chip 141, 142, and a structure 300 between the chip 141, 142 and the package lid 130, including a thermal interface material (TIM) layer 170, and a metal layer 151, 152 between the TIM layer 170 and at least one of the chip 141, 142 or the package lid 130, and configured to inhibit formation of an intermetallic compound (IMC) layer 191, 192.

In one embodiment, the metal layer 151, 152 may include Cu (111). In one embodiment, the TIM layer 170 may include a metal TIM layer 170 including at least one of indium, tin, gallium or silver. In one embodiment, the metal layer 151, 152 may include an first metal layer 151 between the TIM layer 170 and the chip 141, 142, and a second metal layer 152 between the package lid 130 and the TIM layer 170. In one embodiment, at least one of the first metal layer 151 or the second metal layer 152 may include a textured structure. In one embodiment, the IMC layer 191, 192 may include a lower IMC layer 191 between the TIM layer 170 and the first metal layer 151, and an upper IMC layer 192 between the TIM layer 170 and the second metal layer 152. In one embodiment, an amount of columnar grain in at least one of the first metal layer 151 or second metal layer 152 may be greater than 95%. In one embodiment, an area of the TIM layer 170 may be greater than or equal to an area of the first metal layer 151. In one embodiment, the area of the second metal layer 152 may be greater than or equal to an area of the TIM layer 170. In one embodiment, the thickness T₁₅₁ of the first metal layer 151 may be greater than or equal to a thickness T₁₅₂ of the second metal layer 152. In one embodiment, the thickness T₁₇₀ of the TIM layer 170 may be greater than or equal to a thickness T₁₅₁ of the first metal layer 151. In one embodiment, at least one of a first interface between the first metal layer 151 and the TIM layer 170 or a second interface between the second metal layer 152 and the TIM layer 170 is substantially free of voids.

Referring again to FIGS. 1A-8, a method of making a package structure 100 may include forming a metal layer 151, 152 including a high-texture structure on at least one of an interposer module 120 or a package lid 130, attaching the interposer module 120 to a package substrate 110, forming a thermal interface material (TIM) layer 170 over the interposer module 120, and attaching the package lid 130 to the package substrate 110 over the interposer module 120 so that the interposer module 120, the TIM layer 170 and the metal layer 151, 152 are disposed between the package lid 130 and the package substrate 120. In one embodiment, the method may further include forming an intermetallic compound (IMC) layer between the TIM layer and the metal layer, and the forming of the metal layer 151, 152 may include forming a first metal layer 151 on the interposer module 120, such that the IMC layer includes a lower IMC layer between the TIM layer 170 and second metal layer 152, and forming a second metal layer 152 on the package lid 130, wherein the second metal layer 152 may include Cu (111). In one embodiment, the forming of the first metal layer 151 may include forming the first metal layer 151 to include a textured structure, and the forming of the second metal layer 152 may include forming the second metal layer 152 to include a textured structure. In one embodiment, the forming of the TIM layer 170 may include forming the TIM layer 170 to have an area greater than or equal to an area of the first metal layer 151 and a thickness T₁₇₀ greater than or equal to a thickness T₁₅₁ of the first metal layer 151. In one embodiment, the forming of the second metal layer 152 may include forming the second metal layer 152 to have an area greater than or equal to an area of the TIM layer 170 and a thickness T₁₅₂ less than or equal to a thickness T₁₅₁ of the first metal layer 151. In one embodiment, method may further include forming a graphite film adjacent the TIM layer 170.

Referring again to FIGS. 1A-8, a package structure 100 may include a package substrate 110, a chip 141, 142 on the package substrate 110, a package lid 130 over the chip 141, 142, a thermal interface material (TIM) layer 170, and a metal layer 151, 152 adjacent the TIM layer 170 and including a high-texture structure. In at least one embodiment, the TIM layer 170 may include an extension portion 170x located outside the chip 141, 142 and projecting one of downwardly at an angle with respect to a sidewall of the chip 141, 142, downwardly in a direction along the sidewall of the chip 141, 142 toward the package substrate 110, or laterally and contacting an inner sidewall of a foot portion 130a of the package lid 130. In at least one embodiment, the package lid 130 may include a plate portion 130d over the chip 141, 142, a foot portion 130a attached to the plate portion 130d and attached to the package substrate 110, and a dam structure 130pd projecting from a bottom surface S₁₃₀ₚ of the plate portion 130p between the TIM layer 170 and the foot portion 130a.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a package substrate;
a chip over the package substrate;
a package lid over the chip; and
a structure between the chip and the package lid, comprising:
a thermal interface material (TIM) layer; and
a high-texture layer adjacent the TIM layer.

2. The package structure according to claim 1, wherein the high-texture layer comprises an amount of grains oriented in a particular direction greater than 75%.

3. The package structure of claim 1, wherein the TIM layer comprises a metal TIM layer including at least one of indium, tin, gallium or silver.

4. The package structure of claim 1, wherein the high-texture layer comprises:
a first metal layer between the TIM layer and the chip; and
a second metal layer between the package lid and the TIM layer.

5. The package structure of claim 4, wherein a width of the first metal layer is substantially equal to a width of the chip.

6. The package structure of claim 4, wherein the high-texture layer is configured to inhibit a formation of an intermetallic compound (IMC) layer that comprises a lower IMC layer between the TIM layer and the first metal layer, and an upper IMC layer between the TIM layer and the second metal layer.

7. The package structure of claim 4, wherein an area of the TIM layer is greater than or equal to an area of the second metal layer.

8. The package structure of claim 4, wherein an area of the second metal layer is greater than or equal to an area of the TIM layer.

9. The package structure of claim 4, wherein a thickness of the first metal layer is greater than or equal to a thickness of the second metal layer.

10. The package structure of claim 4, wherein a thickness of the TIM layer is greater than or equal to a thickness of the first metal layer.

11. The package structure of claim 4, wherein at least one of a first interface between the first metal layer and the TIM layer or a second interface between the second metal layer and the TIM layer is substantially free of voids.

12. A method of making a package structure, the method comprising:
attaching a chip to a package substrate;
forming a thermal interface material (TIM) layer on the chip; and
attaching a package lid to the package substrate over the chip so that the chip and the TIM layer are disposed between the package lid and the package substrate;
wherein a metal layer with a high-texture structure is disposed between the chip and the package lid.

13. The method of claim 12, further comprising:
forming the metal layer comprising:
forming a first metal layer on the chip, wherein the first metal layer includes Cu (111); and
forming a second metal layer on the package lid, wherein the second metal layer includes Cu (111).

14. The method of claim 13, wherein the forming of the first metal layer comprises forming the first metal layer to include a textured structure and the forming of the second metal layer comprises forming the second metal layer to include a textured structure.

15. The method of claim 13, wherein the forming of the TIM layer comprises forming the TIM layer to have an area greater than or equal to an area of the first metal layer and a thickness greater than or equal to a thickness of the first metal layer.

16. The method of claim 13, wherein the forming of the second metal layer comprises forming the second metal layer to have an area greater than or equal to an area of the TIM layer and a thickness less than or equal to a thickness of the first metal layer.

17. The method of claim 12, wherein the forming of the TIM layer comprises forming a hybrid TIM layer comprising:
a first metal TIM layer;
a graphite film on the first metal TIM layer; and
a second metal TIM layer on the graphite film.

18. A package structure, comprising:
a chip over a package substrate;
a thermal interface material (TIM) layer over the chip;
a package lid over the TIM layer; and
a metal layer disposed overlying or underlying the TIM layer, wherein the metal layer comprises twin boundaries with a density greater than 10 boundaries per m length.

19. The package structure of claim 18, wherein the TIM layer comprises an extension portion located outside the chip and projecting one of:
downwardly at an angle with respect to a sidewall of the chip;
downwardly in a direction along the sidewall of the chip toward the package substrate; or
laterally and contacting an inner sidewall of a foot portion of the package lid.

20. The package structure of claim 18, wherein the package lid comprises:
a plate portion over the chip;
a foot portion attached to the plate portion and attached to the package substrate; and
a dam structure projecting from a bottom surface of the plate portion between the TIM layer and the foot portion.
